(19) United States
(12) Patent Application Publication
(10) Pub. No.: US 2025/0218519 A1
(43) Pub. Date: Jul. 3, 2025

(54) SEMICONDUCTOR STORAGE DEVICE, CONTROL METHOD OF SEMICONDUCTOR STORAGE DEVICE, AND MANUFACTURING METHOD OF SEMICONDUCTOR STORAGE DEVICE

(71) Applicant: Kioxia Corporation, Tokyo (JP)

(72) Inventor: Yoichi MINEMURA, Yokkaichi Mie (JP)

(73) Assignee: Kioxia Corporation, Tokyo (JP)

(21) Appl. No.: 18/829,528

(22) Filed: Sep. 10, 2024

(30) Foreign Application Priority Data
Dec. 28, 2023 (JP) 2023-222629

(51) Int. Cl. G11C 16/34; G11C 16/04; G11C 16/10; H10B 41/27; H10B 43/27

(52) U.S. Cl. CPC G11C 16/3427; G11C 16/0483; G11C 16/10; H10B 41/27; H10B 43/27; G11C 2216/02

(57) ABSTRACT

A semiconductor storage device according to one embodiment includes a multi-layered body and a columnar body. The multi-layered body includes a plurality of gate electrode layers and a plurality of insulating layers.

### CROSS-REFERENCE TO RELATED APPLICATION

This application is based upon and claims the benefit of priority from Japanese Patent Application No. 2023-222629 filed on Dec. 28, 2023; the entire contents of which are incorporated herein by reference.

### FIELD

Embodiments of the present invention relate to a semiconductor storage device, a control method of the semiconductor storage device, and a manufacturing method of the semiconductor storage device.

### BACKGROUND ART

A semiconductor storage device including a multi-layered body and a columnar body is known. In the semiconductor storage device, conductive layers and insulating layers are alternately stacked one by one. The columnar body penetrates the multi-layered body.

### BRIEF DESCRIPTION OF THE DRAWINGS

FIG. 1 is a block diagram showing a part of a configuration of a semiconductor storage device according to a first embodiment.

FIG. 2 is a diagram showing an equivalent circuit of a part of a memory cell array according to the first embodiment.

FIG. 3 is a cross-sectional view showing a part of the semiconductor storage device according to the first embodiment.

FIG. 4 is an enlarged cross-sectional view showing the region surrounded by line F4 of the semiconductor storage device shown in FIG. 3.

FIG. 5 is a cross-sectional view along line F5-F5 of the semiconductor storage device shown in FIG. 4.

FIG. 6 is an enlarged cross-sectional view showing the region surrounded by line F6 of the semiconductor storage device shown in FIG. 4.

FIG. 7 is a cross-sectional view along line F7-F7 of the semiconductor storage device shown in FIG. 6.

FIG. 8 is a cross-sectional view along line F8-F8 of the semiconductor storage device shown in FIG. 6.

FIG. 9 is a cross-sectional view along line F9-F9 of the semiconductor storage device shown in FIG. 3.

FIG. 10 is an enlarged cross-sectional view showing the region surrounded by line F10 of the semiconductor storage device shown in FIG. 9.

FIG. 11 is a view showing an order of write operations of the semiconductor storage device according to the first embodiment.

FIG. 12 is a view schematically showing a memory pillar according to the first embodiment.

FIG. 13 is a timing chart for explaining a write operation according to the first embodiment.

FIG. 14A is a cross-sectional view for explaining a manufacturing method of the semiconductor storage device according to the first embodiment.

FIG. 14B is a cross-sectional view for explaining the manufacturing method of the semiconductor storage device according to the first embodiment.

FIG. 15 is a cross-sectional view for explaining an operation of the semiconductor storage device according to the first embodiment.

FIG. 16 is a cross-sectional view showing a semiconductor storage device according to a second embodiment.

FIG. 17 is a cross-sectional view showing a semiconductor storage device according to a third embodiment.

FIG. 18 is a cross-sectional view showing a semiconductor storage device according to a fourth embodiment.

FIG. 19 is a cross-sectional view showing a semiconductor storage device according to a fifth embodiment.

### DETAILED DESCRIPTION

A semiconductor storage device according to one embodiment includes a multi-layered body and a columnar body. The multi-layered body includes a plurality of gate electrode layers and a plurality of insulating layers. The plurality of gate electrode layers and the plurality of insulating layers are alternately stacked one by one in a first direction. The columnar body extends in the first direction within the multi-layered body. The columnar body includes a memory film and a channel layer. The plurality of gate electrode layers include a first gate electrode layer and a second gate electrode layer. The second gate electrode layer is on a first side in the first direction with respect to the first gate electrode layer. The second gate electrode layer is adjacent to the first gate electrode layer among the plurality of gate electrode layers. The plurality of insulating layers include a first insulating layer and a second insulating layer. The first insulating layer is adjacent to the first gate electrode layer from a second side opposite to the first side in the first direction. The second insulating layer is between the first gate electrode layer and the second gate electrode layer. When a direction orthogonal to the first direction is defined as a second direction, when viewed in a cross section in the first direction and the second direction, a first boundary is between the first gate electrode layer and the first insulating layer, the first boundary extends in the second direction, a second boundary is between the first gate electrode layer and the second insulating layer, the second boundary extends in the second direction, a third boundary is between the second gate electrode layer and the second insulating layer, and the third boundary extends in the second direction. The first gate electrode layer has a first edge adjacent to the columnar body at the first boundary. The first gate electrode layer has a second edge adjacent to the columnar body from a side opposite to the first edge at the first boundary. A distance between the first edge and the second edge is defined as a first distance. The first gate electrode layer has a third edge adjacent to the columnar body at the second boundary. The first gate electrode layer has a fourth edge adjacent to the columnar body from a side opposite to the third edge at the second boundary. A distance between the third edge and the fourth edge is defined as a second distance. The second gate electrode layer has a fifth edge adjacent to the columnar body at the third boundary. The second gate electrode layer has a sixth edge adjacent to the columnar body from a side opposite to the fifth edge at the third boundary. A distance between the fifth edge and the sixth edge is defined as a third distance. The second distance is larger than the first distance and larger than the third distance.

Hereinafter, a semiconductor storage device, a control method of the semiconductor storage device, and a manufacturing method of the semiconductor storage device according to embodiments will be described with reference to the drawings. In the following description, components having the same or similar functions are denoted by the same reference signs. Also, duplicate description of the components may be omitted. In the following description, when a reference sign is appended with a number or an alphabetical letter at the end for distinction, the number or the alphabetical letter at the end may be omitted when there is no need for distinguishing.

In the present application, terms are defined as follows. “Parallel”, “orthogonal”, or “the same” may include a case of “substantially parallel”, “substantially orthogonal”, or “substantially the same”. “Connection” is not limited to a case of being mechanically connected, and may also include a case of being electrically connected. That is, “connection” is not limited to a case in which a plurality of elements are directly connected, and may include a case in which a plurality of elements are connected with another element interposed therebetween. “Adjacent” and “adjacent to each other” are not limited to a case in which elements are in contact with each other, and may also include a case in which they are aligned with another element interposed therebetween.

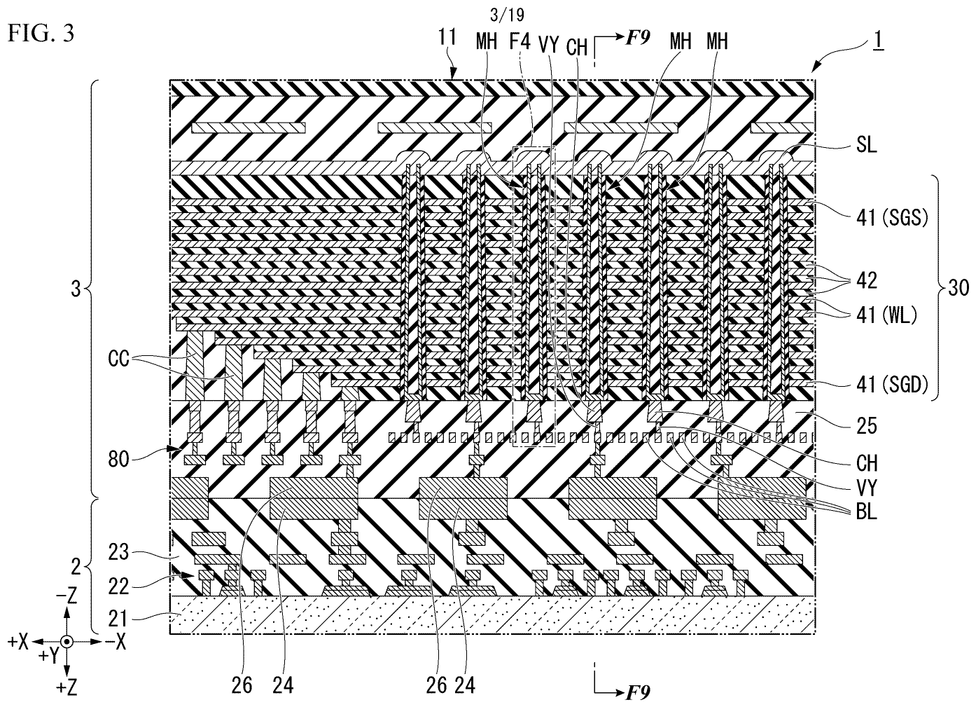

A +X direction, a −X direction, a +Y direction, a −Y direction, a +Z direction, and a −Z direction are defined as follows. The +X direction is a direction in which a word line WL to be described later extends (see FIG. 3). The −X direction is a direction opposite to the +X direction. In a case in which the +X direction and the −X direction do not need to be distinguished from each other, they will be simply referred to as an “X direction”. The +Y direction is a direction that intersects (for example, is orthogonal to) the X direction. The +Y direction is a direction in which a bit line BL extends (see FIG. 3). The −Y direction is a direction opposite to the +Y direction. In a case in which the +Y direction and the −Y direction do not need to be distinguished from each other, they will be simply referred to as a “Y direction”. The +Z direction is a direction that is orthogonal to the X direction and the Y direction. The +Z direction is a direction toward the bit line BL from a multi-layered body 30 to be described later (see FIG. 3). The −Z direction is a direction opposite to the +Z direction. In a case in which the +Z direction and the −Z direction do not need to be distinguished from each other, they will be simply referred to as a “Z direction”. In the following description, a position in the Z direction may be referred to using a “height”. The Z direction is an example of a “first direction”. The X direction is an example of a “second direction”. In the drawings described below, illustration of components not related to the description may be omitted.

### First Embodiment

### <1. Configuration of Semiconductor Storage Device>

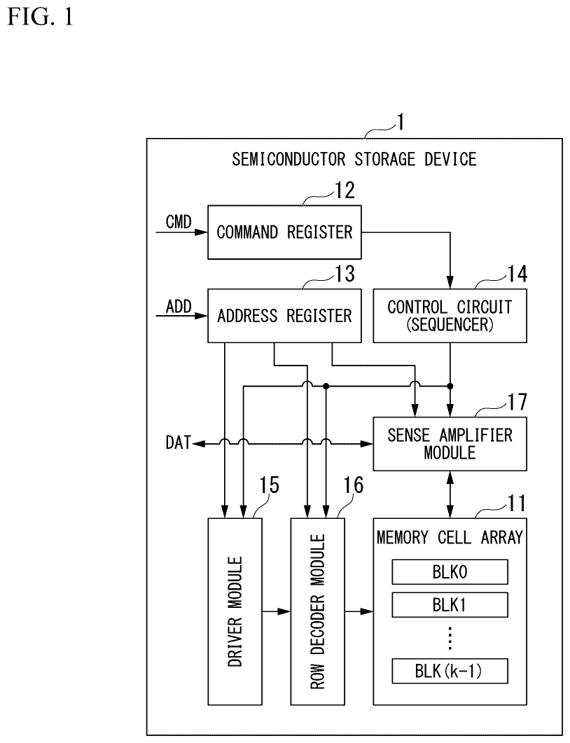

FIG. 1 is a block diagram showing a part of a configuration of a semiconductor storage device 1. The semiconductor storage device 1 is, for example, a nonvolatile semiconductor storage device and is a NAND type flash memory. The semiconductor storage device 1 can be connected to an external host device and can be used as a storage space for the host device. The semiconductor storage device 1 includes, for example, a memory cell array 11, a command register 12, an address register 13, a control circuit (sequencer) 14, a driver module 15, a row decoder module 16, and a sense amplifier module 17.

The memory cell array 11 includes a plurality of blocks BLK0 to BLK(k−1) (k is an integer of 1 or more). A plurality of memory cell transistors are provided in the block BLK. The block BLK is used as a data erasing unit. A plurality of bit lines and a plurality of word lines are provided in the memory cell array 11. Each of the memory cell transistors is associated with one bit line and one word line.

The command register 12 holds a command CMD received by the semiconductor storage device 1 from the host device. The address register 13 holds address information ADD received by the semiconductor storage device 1 from the host device. The address information ADD is used to select a block BLK, a word line, and a bit line. The control circuit 14 controls various operations of the semiconductor storage device 1. For example, the control circuit 14 executes a write operation, a read operation, an erase operation, or the like of data based on the command CMD held in the command register 12.

The driver module 15 includes a voltage generator. The voltage generator generates voltages used in various operations of the semiconductor storage device 1. The row decoder module 16 transfers a voltage applied to a signal line corresponding to a selected word line to the selected word line. The sense amplifier module 17 applies a desired voltage to each bit line in the write operation. In the read operation, the sense amplifier module 17 determines data stored in each memory cell transistor based on a voltage or a current of each bit line, and transfers the determination result to the host device as read data DAT.

### <2. Electrical Configuration of Memory Cell Array>

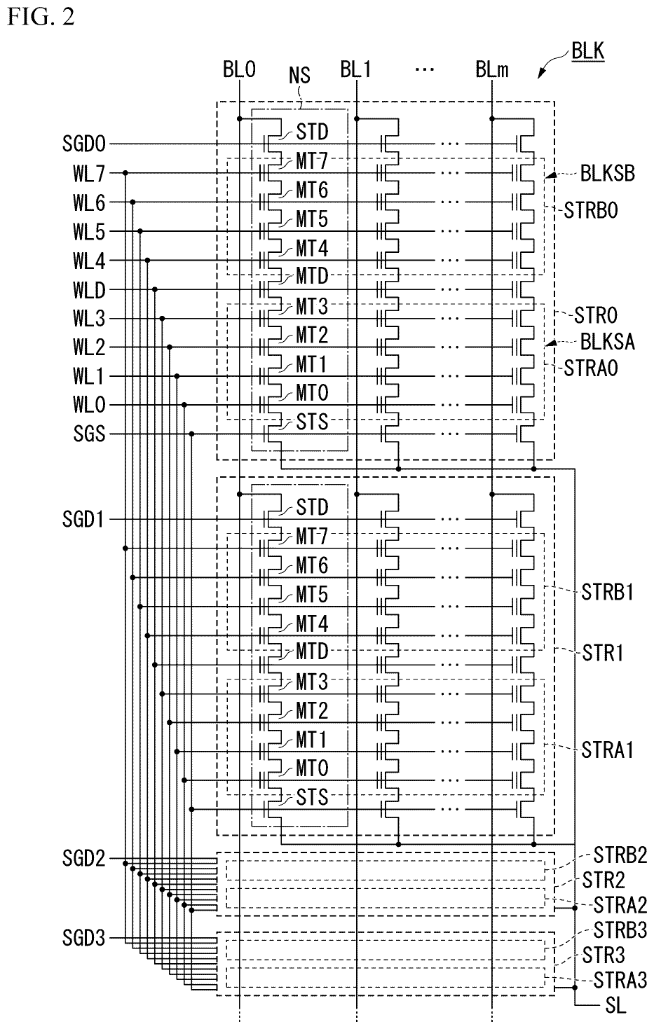

FIG. 2 is a diagram showing an equivalent circuit of a part of the memory cell array 11. FIG. 2 shows one block BLK included in the memory cell array 11. The block BLK includes a plurality of (for example, four) strings STR0 to STR3.

Each string STR includes a plurality of NAND strings NS that are respectively associated with bit lines BL0 to BLm (m is an integer of 1 or more). Each NAND string NS includes, for example, a plurality of memory cell transistors MT0 to MT7, one or more dummy memory cell transistors MTD, one or more drain-side selection transistors STD, and one or more source-side selection transistors STS. Note that, for convenience of explanation, FIG. 2 shows only eight memory cell transistors MT0 to MT7 for each NAND string NS. However, each NAND string NS may include a larger number of the memory cell transistors MT.

In each NAND string NS, the memory cell transistors MT0 to MT7 are electrically connected in series. Each of the memory cell transistors MT includes a control gate and a charge storage portion. The control gate of the memory cell transistor MT is electrically connected to any one of word lines WL0 to WL7. Each memory cell transistor MT stores charge in the charge storage portion according to a voltage applied to the control gate via the word line WL, and stores data non-volatilely.

In the present embodiment, each block BLK includes a first sub-block BLKSA and a second sub-block BLKSB. Each sub-block BLKS is a unit in which data can be erased independently of the other sub-block BLKS included in the same block BLK.

In the example shown in FIG. 2, the first sub-block BLKSA includes substrings STRA0 to STRA3. The substring STRA0 includes the memory cell transistors MT0 to MT3 of each NAND string NS in the string STR0. The substring STRA1 includes the memory cell transistors MT0 to MT3 of each NAND string NS in the string STR1. The substring STRA2 includes the memory cell transistors MT0 to MT3 of each NAND string NS in the string STR2. The substring STRA3 includes the memory cell transistors MT0 to MT3 of each NAND string NS in the string STR3. Note that, for convenience of explanation, only four memory cell transistors MT0 to MT3 are shown for each substring STRA in FIG. 2. However, each substring STRA may include a larger number of the memory cell transistors MT.

Similarly, the second sub-block BLKSB includes substrings STRB0 to STRB3. The substring STRB0 includes the memory cell transistors MT4 to MT7 of each NAND string NS in the string STR0. The substring STRB1 includes the memory cell transistors MT4 to MT7 of each NAND string NS in the string STR1. The substring STRB2 includes the memory cell transistors MT4 to MT7 of each NAND string NS in the string STR2. The substring STRB3 includes the memory cell transistors MT4 to MT7 of each NAND string NS in the string STR3. Note that, for convenience of explanation, only four memory cell transistors MT4 to MT7 are shown for each substring STRB in FIG. 2. However, each substring STRB may include a larger number of the memory cell transistors MT.

The dummy memory cell transistor MTD has the same configuration as the memory cell transistor MT, but is not used to store valid data. In each NAND string NS, the dummy memory cell transistor MTD is disposed between the memory cell transistors MT0 to MT3 included in the first sub-block BLKSA and the memory cell transistors MT4 to MT7 included in the second sub-block BLKSB. The dummy memory cell transistor MTD is disposed, for example, to suppress an influence of a data erasing operation on other sub-blocks BLKS (for example, sub-blocks BLKS in which data is not to be erased) when data in a certain sub-block BLKS is erased. Note that, the number of dummy memory cell transistors MTD disposed between two sub-blocks BLKS in each NAND string NS is not limited to one, and may be two or more.

A drain of the drain-side selection transistor STD is electrically connected to the bit line BL corresponding to the NAND string NS. A source of the drain-side selection transistor STD is electrically connected to one end of the memory cell transistors MT0 to MT7 that are electrically connected in series. A control gate of the drain-side selection transistor STD is electrically connected to any one of the drain-side selection gate lines SGD0 to SGD3. The drain-side selection transistor STD is electrically connected to the row decoder module 16 via the drain-side selection gate line SGD. The drain-side selection transistor STD electrically connects the NAND string NS and the bit line BL when a predetermined voltage is applied to the corresponding drain-side selection gate line SGD.

A drain of the source-side selection transistor STS is electrically connected to the other end of the memory cell transistors MT0 to MT7 that are electrically connected in series. A source of the source-side selection transistor STS is electrically connected to a source line SL. A control gate of the source-side selection transistor STS is electrically connected to a source-side selection gate line SGS. The source-side selection transistor STS electrically connects the NAND string NS and the source line SL when a predetermined voltage is applied to the source-side selection gate line SGS.

In the same block BLK, the control gates of the memory cell transistors MT0 to MT7 are commonly electrically connected to the word lines WL0 to WL7 in one-to-one correspondence. Also, in the same block BLK, the control gates of the dummy memory cell transistors MTD are commonly electrically connected to a dummy word line WLD. In the same string STR, the control gates of the drain-side selection transistors STD are commonly electrically connected to the corresponding drain-side selection gate lines SGD0 to SGD3. The control gates of the source-side selection transistors STS are commonly electrically connected to the source-side selection gate line SGS. In the memory cell array 11, the bit line BL is shared by the NAND strings NS to which the same column address is assigned in the plurality of strings STR.

### <3. Physical Configuration of Semiconductor Storage Device>

Next, a physical configuration of the semiconductor storage device 1 will be described.

FIG. 3 is a cross-sectional view showing a part of the semiconductor storage device 1. The semiconductor storage device 1 includes, for example, a first chip 2 and a second chip 3.

### <3.1 First Chip>

The first chip 2 is a circuit chip including peripheral circuits. The first chip 2 includes, for example, a semiconductor substrate 21, a peripheral circuit 22, an insulating portion 23, and a plurality of pads 24.

The semiconductor substrate 21 is a substrate that serves as a base portion of the first chip 2. At least a part of the semiconductor substrate 21 has a plate shape extending in the X direction and the Y direction. The peripheral circuit 22 is a circuit configured to realize the above-described function of the memory cell array 11. The peripheral circuit 22 includes one or more of the command register 12, the address register 13, the control circuit 14, the driver module 15, the row decoder module 16, and the sense amplifier module 17 described above. The insulating portion 23 covers the peripheral circuit 22. The plurality of pads 24 are provided on a surface of the insulating portion 23. Each of the pads 24 is electrically connected to the peripheral circuit 22.

### <3.2 Second Chip>

The second chip 3 is an array chip that includes the memory cell array 11. The second chip 3 includes, for example, the memory cell array 11, an insulating portion 25, and a plurality of pads 26. Here, the insulating portion 25 and the pads 26 will be described, and the memory cell array 11 will be described later.

The insulating portion 25 covers the memory cell array 11. The plurality of pads 26 are provided on a surface of the insulating portion 25. Each pad 26 is electrically connected to a wiring included in the memory cell array 11. In the present embodiment, the first chip 2 and the second chip 3 are integrated by bonding the plurality of pads 24 of the first chip 2 and the plurality of pads 26 of the second chip 3 to face each other.

### <4. Physical Configuration of Memory Cell Array>

Next, a physical configuration of the memory cell array 11 will be described.

As shown in FIG. 3, the memory cell array 11 has the multi-layered body 30, a source line SL, a plurality of memory pillars MH, a plurality of bit lines BL, a plurality of contacts CH for the memory pillars, a plurality of contacts VY for the memory pillars, a plurality of contacts CC for at least one of a plurality of conductive layers to be described later, and a wiring portion 80.

### <4.1 Multi-Layered Body>

First, the multi-layered body 30 will be described.

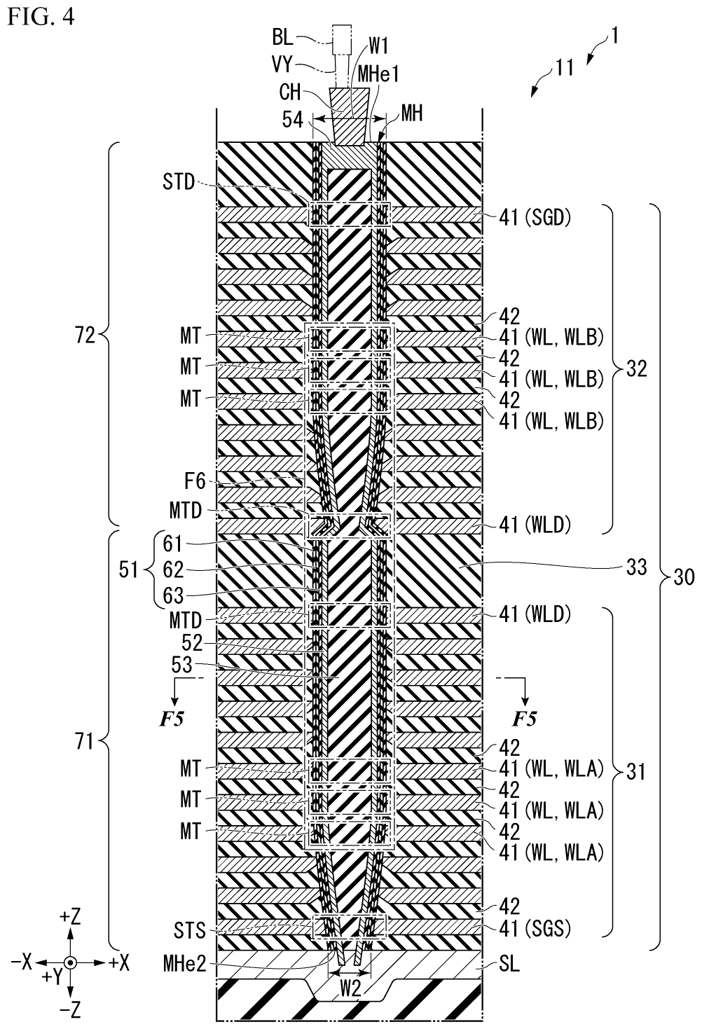

FIG. 4 is an enlarged cross-sectional view showing the region surrounded by line F4 of the semiconductor storage device 1 shown in FIG. 3. Note that, from FIG. 4 onward, the configuration of the semiconductor storage device 1 is shown with a posture in which the +Z direction is an upper side and the −Z direction is a lower side. In the following description, the side in the +Z direction may be referred to using “upper” and the side in the −Z direction may be referred to using “lower”. However, these expressions are used for convenience of explanation and do not define a direction of gravity.

The multi-layered body 30 includes a first multi-layered body 31, a second multi-layered body 32, and an intermediate insulating layer 33. The first multi-layered body 31 is disposed on the side in the +Z direction with respect to the source line SL. The second multi-layered body 32 is disposed on the side in the +Z direction with respect to the first multi-layered body 31. The intermediate insulating layer 33 is disposed between the first multi-layered body 31 and the second multi-layered body 32 in the Z direction. A thickness of the intermediate insulating layer 33 in the Z direction is equal to or larger than the thickness in the Z direction of an insulating layer 42 to be described later. The intermediate insulating layer 33 is formed of, for example, a film containing silicon and oxygen.

Each of the first multi-layered body 31 and the second multi-layered body 32 includes the plurality of conductive layers 41 and a plurality of insulating layers 42. In each of the first multi-layered body 31 and the second multi-layered body 32, the plurality of conductive layers 41 and the plurality of insulating layers 42 are alternately stacked one by one in the Z direction.

The conductive layer 41 is a layer extending in the X direction and the Y direction, and has conductivity. Each conductive layer 41 contains a conductive material such as, for example, tungsten, molybdenum, or silicon doped with impurities. The conductive layer 41 is an example of a “gate electrode layer”.

In the multi-layered body 30, one or more conductive layers 41 positioned on an upper side of the plurality of conductive layers 41 can function as the drain-side selection gate line SGD. The drain-side selection gate line SGD is commonly provided for the plurality of memory pillars MH aligned in the X direction and the Y direction. A portion in which the drain-side selection gate line SGD and a channel layer 52 (to be described later) of each memory pillar MH intersect functions as the drain-side selection transistor STD described above.

In the multi-layered body 30, one or more conductive layers 41 positioned on a lower side of the plurality of conductive layers 41 can function as the source-side selection gate line SGS. The source-side selection gate line SGS is commonly provided for the plurality of memory pillars MH aligned in X direction and the Y direction. A portion in which the source-side selection gate line SGS and the channel layer 52 of each memory pillar MH intersect functions as the source-side selection transistor STS described above.

In the multi-layered body 30, the plurality of conductive layers 41 include the conductive layer 41 that functions as the drain-side selection gate line SGD. This conductive layer 41 can be referred to as a first conductive layer. The plurality of conductive layers 41 includes a conductive layer 41 that functions as the source-side selection gate line SGS. This conductive layer 41 can be referred to as a second conductive layer. In the multi-layered body 30, at least a part of the remaining conductive layers 41 provided between the first conductive layer and the second conductive layer can function as the word line WL. The word line WL is commonly provided for the plurality of memory pillars MH aligned in the X direction and the Y direction. In the present embodiment, a portion in which the word line WL and the channel layer 52 of each memory pillar MH intersect functions as the memory cell transistor MT. The memory cell transistor MT will be described in detail later.

In the present embodiment, the plurality of word lines WL include a plurality of word lines WLA corresponding to the first sub-block BLKSA and a plurality of word lines WLB corresponding to the second sub-block BLKSB. The plurality of word lines WLA are included in the first multi-layered body 31. The plurality of word lines WLB are included in the second multi-layered body 32.

In the multi-layered body 30, at least another part of the remaining conductive layers 41 provided between the first conductive layer and the second conductive layer can function as the dummy word line WLD. The dummy word line WLD is commonly provided for the plurality of memory pillars MH aligned in the X direction and the Y direction. In the present embodiment, a portion in which the dummy word line WLD and the channel layer 52 of each memory pillar MH intersect functions as the dummy memory cell transistor MTD.

In the present embodiment, one or more conductive layers positioned on an uppermost side among the plurality of conductive layers 41 included in the first multi-layered body 31 can be referred to as upper conductive layers. Of the plurality of conductive layers 41 included in the second multi-layered body 32, one or more conductive layers positioned on a lowermost side can be referred to as lower conductive layers. One or more upper conductive layers and the one or more lower conductive layers function as the dummy word lines WLD. In other words, the dummy word lines WLD are disposed between the plurality of word lines WLA and the plurality of word lines WLB in the Z direction.

The insulating layer 42 is provided between two conductive layers 41 adjacent to each other in the Z direction. The insulating layer 42 is an insulating film that insulates the two conductive layers 41 from each other. The insulating layer 42 is a layer extending in the X direction and the Y direction. The insulating layer 42 contains, for example, silicon and oxygen.

### <4.2 Source Line>

The source line SL is disposed on the side in the −Z direction with respect to the multi-layered body 30. The source line SL is a conductive layer extending in the X direction and the Y direction. The source line SL contains a conductive material such as tungsten, molybdenum, or silicon doped with impurities.

### <4.3 Memory Pillar>

The plurality of memory pillars MH are aligned in the X direction and the Y direction (see FIG. 3). The memory pillars MH each extend in the Z direction within the multi-layered body 30. Each memory pillar MH penetrates the multi-layered body 30. A lower end of each memory pillar MH is in contact with the source line SL. An upper end of each memory pillar MH is in contact with the contact CH to be described later. The memory pillar MH is an example of a “columnar body”.

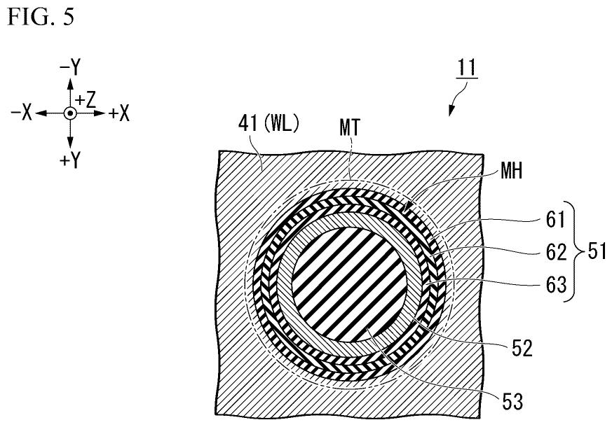

FIG. 5 is a cross-sectional view along line F5-F5 of the semiconductor storage device 1 shown in FIG. 4. The memory pillar MH includes, for example, a memory film (multilayer film) 51, a channel layer 52, an insulating core 53, and a cap portion 54 (see FIG. 4).

The memory film 51 is provided on an outer circumferential side of the channel layer 52. The memory film 51 is positioned between the plurality of conductive layers 41 and the channel layer 52. The memory film 51 includes, for example, a block insulating film 61, a charge trap film 62, and a tunnel insulating film 63.

The block insulating film 61 is provided between the plurality of conductive layers 41 and the charge trap film 62. The block insulating film 61 is an insulating film that suppresses back tunneling. Back tunneling is a phenomenon in which charge returns from the word line WL to the charge trap film 62. The block insulating film 61 is formed in an annular shape and extends in the Z direction. The block insulating film 61 is formed, for example, over the entire length of the memory pillar MH in the Z direction. The block insulating film 61 is a multi-layered structure film in which a plurality of insulating films such as, for example, a film containing silicon and oxygen or a film containing a metal and oxygen are stacked. An example of the film containing a metal and oxygen is aluminum oxide. The block insulating film 61 may contain a high dielectric constant material (high-k material) such as silicon nitride or hafnium oxide.

The charge trap film 62 is positioned between the block insulating film 61 and the tunnel insulating film 63. The charge trap film 62 is formed in an annular shape and extends in the Z direction. The charge trap film 62 is formed, for example, over the entire length of the memory pillar MH in the Z direction. The charge trap film 62 is a functional film that has a large number of crystal defects (trapping levels) and is capable of trapping charges in the crystal defects. The charge trap film 62 contains, for example, silicon and nitrogen. A portion of the charge trap film 62 adjacent to each word line WL is an example of a “charge storage portion” capable of storing information by storing charges.

The tunnel insulating film 63 is provided between the channel layer 52 and the charge trap film 62. The tunnel insulating film 63 has, for example, an annular shape along an outer circumferential surface of the channel layer 52. The tunnel insulating film 63 extends in the Z direction along the channel layer 52. The tunnel insulating film 63 is formed, for example, over the entire length of the memory pillar MH in the Z direction. The tunnel insulating film 63 is a potential barrier between the channel layer 52 and the charge trap film 62. The tunnel insulating film 63 contains silicon and oxygen, or silicon, oxygen, and nitrogen.

The channel layer 52 is provided inside the memory film 51. The channel layer 52 is formed, for example, in an annular shape. The channel layer 52 extends in the Z direction. The channel layer 52 is formed, for example, over the entire length of the memory pillar MH in the Z direction. The channel layer 52 contains a semiconductor material such as polysilicon. The channel layer 52 may be doped with impurities. When a voltage is applied to the word line WL, the channel layer 52 can electrically connect the bit line BL and the source line SL by forming a channel.

Therefore, at the same height as each word line WL, for example, a metal-Al-nitride-oxide-silicon (MANOS) type memory cell transistor MT is formed by an edge part of the word line WL adjacent to the memory pillar MH, the block insulating film 61, the charge trap film 62, the tunnel insulating film 63, and the channel layer 52. Note that, the memory film 51 may have a floating gate type charge storage portion (floating gate electrode) as the charge storage portion instead of the charge trap film 62. The floating gate electrode contains, for example, silicon doped with impurities.

The insulating core 53 is provided inside the channel layer 52. The insulating core 53 fills at least a part of the inside of the channel layer 52. The insulating core 53 contains silicon and oxygen. A part of the insulating core 53 is formed in a columnar shape along an inner circumferential surface of the channel layer 52. The insulating core 53 may have a space portion (air gap) inside the insulating core 53. The insulating core 53 extends in the Z direction. The insulating core 53 extends over most of the memory pillar MH in the Z direction excluding, for example, an upper end part of the memory pillar MH (see FIG. 4).

Next, returning to FIG. 4, the cap portion 54 will be described. The cap portion 54 is provided on an upper side of the insulating core 53. The cap portion 54 contains a semiconductor material such as amorphous silicon or polysilicon. The cap portion 54 may be doped with impurities. The cap portion 54 is disposed on an inner circumferential side of an upper end part of the memory film 51. The cap portion 54 is formed integrally with the channel layer 52. The cap portion 54, together with an upper end part of the channel layer 52, forms an upper end part of the memory pillar MH. The contact CH is in contact with the cap portion 54 in the Z direction.

As shown in FIG. 4, each memory pillar MH is, for example, a two-stage columnar body in the Z direction. Each memory pillar MH includes a first columnar portion 71 and a second columnar portion 72. The first columnar portion 71 is positioned between the source line SL and the second columnar portion 72 in the Z direction. The second columnar portion 72 is disposed on the side in the +Z direction with respect to the first columnar portion 71. A diameter of at least a part of each of the first columnar portion 71 and the second columnar portion 72 gradually decreases in the −Z direction. In other words, a width of at least a part of each of the first columnar portion 71 and the second columnar portion 72 in the X direction gradually decreases in the −Z direction. In the present embodiment, a width of an upper end of the first columnar portion 71 in the X direction is larger than the width of a lower end of the second columnar portion 72 in the X direction. Also, in the present embodiment, a width W1 in the X direction of an end MHe1 of the memory pillar MH on the side in the +Z direction is larger than the width W2 in the X direction of an end MHe2 of the memory pillar MH on the side in the −Z direction. The width W2 in the X direction of the end MHe2 on the side in the −Z direction means a width in the X direction at a contact position between the memory pillar MH and a surface of the source line SL.

### <4.4 Bit Line>

Next, the bit line BL will be described.

The bit line BL is a wiring for selecting at least one memory pillar MH from among the plurality of memory pillars MH. A plurality of bit lines BL are disposed on the side in the +Z direction of the multi-layered body 30. The plurality of bit lines BL are aligned in the X direction at intervals in the X direction. Each bit line BL extends in the Y direction. Each bit line BL is connected to the channel layer 52 of the memory pillar MH via the contact VY, the contact CH, and the cap portion 54. Therefore, an optionally-selected memory cell transistor MT can be selected from among the plurality of memory cell transistors MT disposed three-dimensionally by a combination of the word line WL and the bit line BL.

### <4.5 Contact for Conductive Layer>

As shown in FIG. 3, the contact CC is an electrical connection portion that electrically connects the conductive layer 41 and a wiring included in the wiring portion 80. The plurality of contacts CC extend in the Z direction. For example, lengths of the plurality of contacts CC in the Z direction are different from each another. One end of each contact CC is electrically connected to the corresponding conductive layer 41. The other end of each contact CC is electrically connected to the wiring included in the wiring portion 80.

### <5. Shape of Word Line>

Next, a shape of the conductive layer 41 according to the present embodiment will be described.

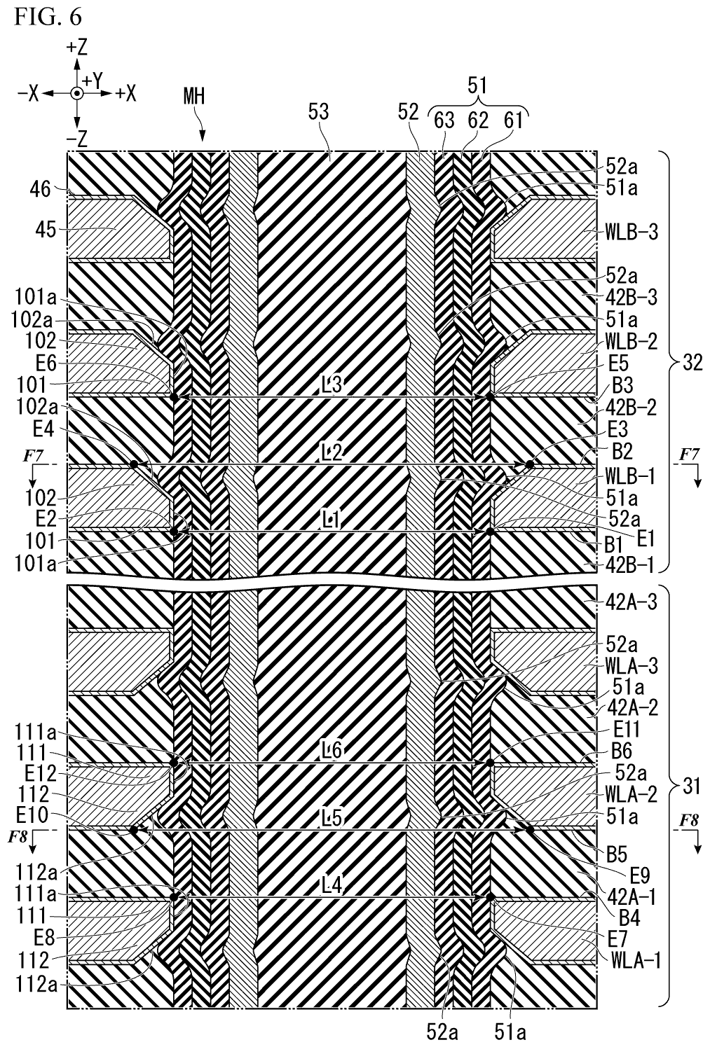

FIG. 6 is an enlarged cross-sectional view showing the region surrounded by the line F6 of the semiconductor storage device 1 shown in FIG. 4. Each word line WL includes a conductive portion 45 and a barrier metal film 46.

The conductive portion 45 is a portion in which a main portion of the word line WL is formed. The conductive portion 45 extends in layers in the X direction and the Y direction. The conductive portion 45 contains the above-described conductive material (for example, tungsten, molybdenum, or silicon doped with impurities).

The barrier metal film 46 is a film for suppressing diffusion of the conductive material contained in the conductive portion 45. The barrier metal film 46 is provided along a surface of the conductive portion 45. For example, the barrier metal film 46 is provided along both a surface on the side in the +Z direction and a surface on the side in the −Z direction of the conductive portion 45. The barrier metal film 46 includes, for example, a material containing titanium, a material containing titanium and nitrogen, a material containing tantalum, a material containing tantalum and nitrogen, a material containing tungsten and nitrogen, or the like.

### (Configuration of Second Multi-Layered Body)

First, a configuration of the second multi-layered body 32 will be described.

As shown in FIG. 6, the plurality of word lines WLB of the second multi-layered body 32 include, for example, a word line WLB-1, a word line WLB-2, and a word line WLB-3. In the present embodiment, on the side in the +Z direction is an example of a “first side”. The word line WLB-1 is an example of a “first gate electrode layer”. The word line WLB-2 is disposed on the side in the +Z direction with respect to the word line WLB-1. The word line WLB-2 is a word line WLB positioned adjacent to the word line WLB-1 among the plurality of word lines WLB. The word line WLB-2 is an example of a “second gate electrode layer”. The word line WLB-3 is disposed on the side in the +Z direction with respect to the word line WLB-2. The word line WLB-3 is a word line WLB positioned adjacent to the word line WLB-2 among the plurality of word lines WLB.

Also, the plurality of insulating layers 42 of the second multi-layered body 32 include, for example, an insulating layer 42B-1, an insulating layer 42B-2, and an insulating layer 42B-3. In the present embodiment, the side in the −Z direction is an example of a “second side”. The insulating layer 42B-1 is adjacent to the word line WLB-1 on the side in the −Z direction. The insulating layer 42B-1 is an example of a “first insulating layer”. The insulating layer 42B-2 is positioned between the word line WLB-1 and the word line WLB-2. The insulating layer 42B-2 is an example of a “second insulating layer”. The insulating layer 42B-3 is positioned between the word line WLB-2 and the word line WLB-3.

### (Shape of Word Line of Second Multi-Layered Body)

Next, a shape of the word line WLB will be described.

In the present embodiment, each word line WLB includes a base portion 101 and a retracted portion 102.

The base portion 101 is included in the word line WLB, for example, between a center of the word line WLB in the Z direction and a surface of the word line WLB on the side in the −Z direction. The base portion 101 has a shape that follows the memory pillar MH in the Z direction. The base portion 101 has an edge 101a adjacent to the memory pillar MH in the X direction.

The retracted portion 102 is positioned on the side in the +Z direction with respect to the base portion 101. The retracted portion 102 is included in the word line WLB, for example, between the center of the word line WLB in the Z direction and a surface of the word line WLB on the side in the +Z direction. At least a part of the retracted portion 102 is retracted with respect to the base portion 101 to become further away from the memory pillar MH in the X direction. For example, the retracted portion 102 is inclined to become further away from the memory pillar MH as it is positioned farther in the +Z direction. The retracted portion 102 has an edge 102a adjacent to the memory pillar MH in the X direction.

In the present embodiment, the memory film 51 of the memory pillar MH has a bulging portion 51a that bulges toward the retracted portion 102 of the word line WLB at a height corresponding to the retracted portion 102 of each word line WLB. Similarly, the channel layer 52 of the memory pillar MH has a bulging portion 52a that bulges toward the retracted portion 102 of the word line WLB at a height corresponding to the retracted portion 102 of each word line WLB. Each of the bulging portion 51a and the bulging portion 52a is formed, for example, in an annular shape when viewed from the Z direction.

In the present embodiment, the base portion 101 of the word line WLB-1 is an example of a “first portion”. The edge 101a of the base portion 101 of the word line WLB-1 is an example of a “first edge part”. The retracted portion 102 of the word line WLB-1 is an example of a “second portion”. The edge 102a of the retracted portion 102 of the word line WLB-1 is an example of a “second edge part”. The edge 102a of the word line WLB-1 is more greatly inclined with respect to the Z direction compared to the edge 101a of the word line WLB-1.

Similarly, the base portion 101 of the word line WLB-2 is an example of a “third portion”. The edge 101a of the base portion 101 of the word line WLB-2 is an example of a “third edge part”. The retracted portion 102 of the word line WLB-2 is an example of a “fourth portion”. The edge 102a of the retracted portion 102 of the word line WLB-2 is an example of a “fourth edge part”. The edge 102a of the word line WLB-2 is more greatly inclined with respect to the Z direction compared to the edge 101a of the word line WLB-2.

### (Dimensional Relationship Between Word Lines of Second Multi-Layered Body)

Next, a dimensional relationship of the word lines WLB of the second multi-layered body 32 will be described.

When viewed in the cross section (the cross section in the X direction and the Z direction) shown in FIG. 6, the following dimensional relationships are satisfied. The word line WLB-1 has a first edge E1 and a second edge E2 at a first boundary B1 which is a boundary in the X direction between the word line WLB-1 and the insulating layer 42B-1. The first edge E1 is adjacent to the memory pillar MH in the X direction. The second edge E2 is adjacent to the memory pillar MH from a side opposite to the first edge E1 in the X direction. A distance in the X direction between the first edge E1 and the second edge E2 is defined as a first distance L1.

Also, the word line WLB-1 has a third edge E3 and a fourth edge E4 at a second boundary B2 which is a boundary in the X direction between the word line WLB-1 and the insulating layer 42B-2. The third edge E3 is adjacent to the memory pillar MH in the X direction. The fourth edge E4 is adjacent to the memory pillar MH from a side opposite to the third edge E3 in the X direction. A distance in the X direction between the third edge E3 and the fourth edge E4 is defined as a second distance L2.

Also, the word line WLB-2 has a fifth edge E5 and a sixth edge E6 at a third boundary B3 which is a boundary in the X direction between the word line WLB-2 and the insulating layer 42B-2. The fifth edge E5 is adjacent to the memory pillar MH in the X direction. The sixth edge E6 is adjacent to the memory pillar MH from a side opposite to the fifth edge E5 in the X direction. A distance in the X direction between the fifth edge E5 and the sixth edge E6 is defined as a third distance L3.

In this case, the second distance L2 is larger than the first distance L1 and larger than the third distance L3. Also, from another perspective, a shortest distance between the channel layer 52 and the third edge E3 is larger than the shortest distance between the channel layer 52 and the first edge E1, and is also larger than the shortest distance between the channel layer 52 and the fifth edge E5.

This relationship is also satisfied between the other two word lines WLB included in the second multi-layered body 32. For example, the above-described relationship is also satisfied between the word line WLB-2 and the word line WLB-3. In this case, in the above description regarding the word line WLB-1 and the word line WLB-2, the “word line WLB-1” need only be read as the “word line WLB-2”, the “word line WLB-2” need only be read as the “word line WLB-3”, the “insulating layer 42B-1” need only be read as the “insulating layer 42B-2”, and the “insulating layer 42B-2” need only be read as the “insulating layer 42B-3”.

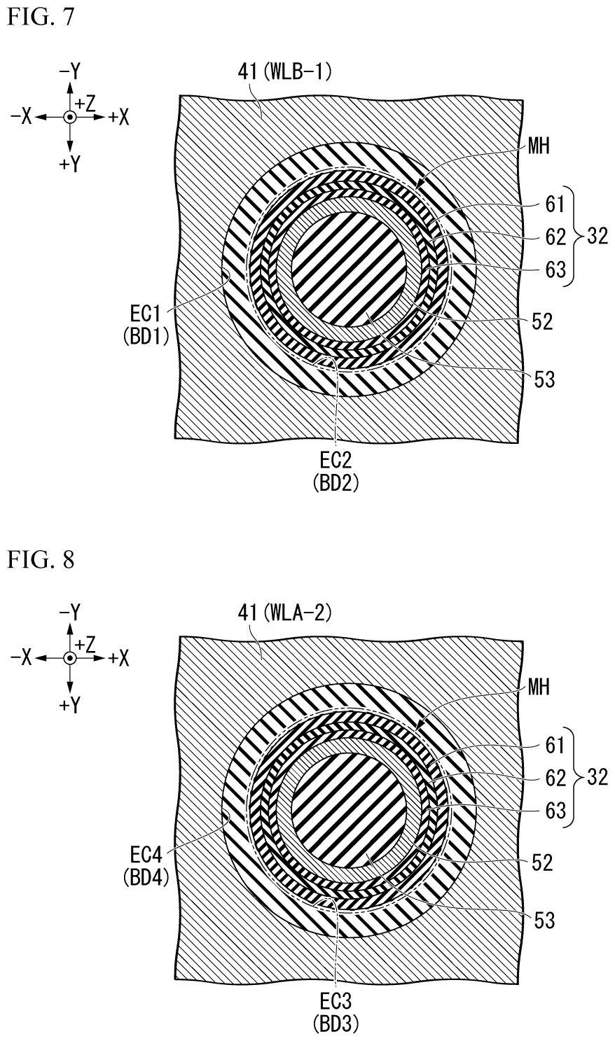

FIG. 7 is a cross-sectional view along line F7-F7 of the semiconductor storage device 1 shown in FIG. 6. As shown in FIG. 6, the second boundary B2 in the X direction is present at the boundary between the word line WLB-1 and the insulating layer 42B-2. As shown in FIG. 7, when viewed from the Z direction, an annular first boundary line BD1 is defined by an annular edge EC1 of the word line WLB-1 at the second boundary B2 (see FIG. 6). The first boundary line BD1 is defined between the word line WLB-1 and the memory pillar MH.

Similarly, as shown in FIG. 6, the third boundary B3 in the X direction is present at the boundary between the word line WLB-2 and the insulating layer 42B-2. As shown in FIG. 7, when viewed from the Z direction, an annular second boundary line BD2 is defined by an annular edge EC2 of the word line WLB-2 at the third boundary B3 (see FIG. 6). The second boundary line BD2 is defined between the word line WLB-2 and the memory pillar MH.

When viewed from the Z direction, the second boundary line BD2 is positioned inside the first boundary line BD1.

This relationship is also satisfied between the other two word lines WLB included in the second multi-layered body 32. For example, the above-described relationship is also satisfied between the word line WLB-2 and the word line WLB-3. In this case, in the above description regarding the word line WLB-1 and the word line WLB-2, the “word line WLB-1” need only be read as the “word line WLB-2”, the “word line WLB-2” need only be read as the “word line WLB-3”, and the “insulating layer 42B-2” need only be read as the “insulating layer 42B-3”.

### (Configuration of First Multi-Layered Body)

Next, a configuration of the first multi-layered body 31 will be described.

As shown in FIG. 6, the plurality of word lines WLA of the first multi-layered body 31 include, for example, a word line WLA-1, a word line WLA-2, and a word line WLA-3. The word line WLA-1 is disposed on the side in the −Z direction with respect to the word line WLB-1. The word line WLA-1 is an example of a “third gate electrode layer”. The word line WLA-2 is disposed between the word line WLA-1 and the word line WLB-1. The word line WLA-2 is a word line WLA positioned adjacent to the word line WLA-1 among the plurality of word lines WLA. The word line WLA-2 is an example of a “fourth gate electrode layer”. The word line WLA-3 is disposed on the side in the +Z direction with respect to the word line WLA-2. The word line WLA-3 is a word line WLB positioned adjacent to the word line WLA-2 among the plurality of word lines WLA.

Also, the plurality of insulating layers 42 of the first multi-layered body 31 include, for example, an insulating layer 42A-1, an insulating layer 42A-2, and an insulating layer 42A-3. The insulating layer 42A-1 is positioned between the word line WLA-1 and the word line WLA-2. The insulating layer 42A-1 is an example of a “third insulating layer”. The insulating layer 42A-2 is positioned between the word line WLA-2 and the word line WLA-3. The insulating layer 42A-2 is adjacent to the word line WLA-2 on the side in the +Z direction. The insulating layer 42A-2 is an example of a “fourth insulating layer”. The insulating layer 42A-3 is adjacent to the word line WLA-3 on the side in the +Z direction.

### (Shape of Word Line of First Multi-Layered Body)

Next, a shape of the word line WLA will be described.

In the present embodiment, each word line WLA includes a base portion 111 and a retracted portion 112.

The base portion 111 is included in the word line WLA, for example, between a center of the word line WLA in the Z direction and a surface of the word line WLA on the side in the +Z direction. The base portion 111 has a shape that follows the memory pillar MH in the Z direction. The base portion 111 has an edge 111a adjacent to the memory pillar MH in the X direction.

The retracted portion 112 is positioned on the side in the −Z direction with respect to the base portion 111. The retracted portion 112 is included in the word line WLA, for example, between the center of the word line WLA in the Z direction and a surface of the word line WLA on the side in the −Z direction. At least a part of the retracted portion 112 is retracted with respect to the base portion 111 to become further away from the memory pillar MH in the X direction. For example, the retracted portion 112 is inclined to become further away from the memory pillar MH as it is positioned farther in the −Z direction. The retracted portion 112 has an edge 112a adjacent to the memory pillar MH in the X direction.

In the present embodiment, the memory film 51 of the memory pillar MH has the bulging portion 51a that bulges toward the retracted portion 112 of the word line WLA at a height corresponding to the retracted portion 112 of each word line WLA. Similarly, the channel layer 52 of the memory pillar MH has a bulging portion 52a that bulges toward the retracted portion 112 of the word line WLA at a height corresponding to the retracted portion 112 of each word line WLA. Each of the bulging portion 51a and the bulging portion 52a is formed, for example, in an annular shape when viewed from the Z direction.

In the present embodiment, the edge 112a of the word line WLA-1 is more greatly inclined with respect to the Z direction compared to the edge 111a of the word line WLA-1. Similarly, the edge 112a of the word line WLA-2 is more greatly inclined with respect to the Z direction compared to the edge 111a of the word line WLA-2.

### (Dimensional Relationship Between Word Lines of First Multi-Layered Body)

Next, a dimensional relationship of the word lines WLA of the first multi-layered body 31 will be described.

When viewed in the cross section (the cross section in the X direction and the Z direction) shown in FIG. 6, the following dimensional relationships are satisfied. The word line WLA-1 has a seventh edge E7 and an eighth edge E8 at a fourth boundary B4 which is a boundary in the X direction between the word line WLA-1 and the insulating layer 42A-1. The seventh edge E7 is adjacent to the memory pillar MH in the X direction. The eighth edge E8 is adjacent to the memory pillar MH from a side opposite to the seventh edge E7 in the X direction. A distance in the X direction between the seventh edge E7 and the eighth edge E8 is defined as a fourth distance L4.

Also, the word line WLA-2 has a ninth edge E9 and a tenth edge E10 at a fifth boundary B5 which is a boundary in the X direction between the word line WLA-2 and the insulating layer 42A-1. The ninth edge E9 is adjacent to the memory pillar MH in the X direction. The tenth edge E10 is adjacent to the memory pillar MH from a side opposite to the ninth edge E9 in the X direction. A distance in the X direction between the ninth edge E9 and the tenth edge E10 is defined as a fifth distance L5.

Also, the word line WLA-2 has an eleventh edge E11 and a twelfth edge E12 at a sixth boundary B6 which is a boundary in the X direction between the word line WLA-2 and the insulating layer 42A-2. The eleventh edge E11 is adjacent to the memory pillar MH in the X direction. The twelfth edge E12 is adjacent to the memory pillar MH from a side opposite to the eleventh edge E11 in the X direction. A distance in the X direction between the eleventh edge E11 and the twelfth edge E12 is defined as a sixth distance L6.

In this case, the fifth distance L5 is larger than the fourth distance L4 and larger than the sixth distance L6. Also, from another perspective, a shortest distance between the channel layer 52 and the ninth edge E9 is larger than the shortest distance between the channel layer 52 and the seventh edge E7, and is also larger than the shortest distance between the channel layer 52 and the eleventh edge E11.

This relationship is also satisfied between the other two word lines WLA included in the first multi-layered body 31. For example, the above-described relationship is also satisfied between the word line WLA-2 and the word line WLA-3. In this case, in the above description regarding the word line WLA-1 and the word line WLA-2, the “word line WLA-1” need only be read as the “word line WLA-2”, the “word line WLA-2” need only be read as the “word line WLA-3”, the “insulating layer 42A-1” need only be read as the “insulating layer 42A-2”, and the “insulating layer 42A-2” need only be read as the “insulating layer 42A-3”.

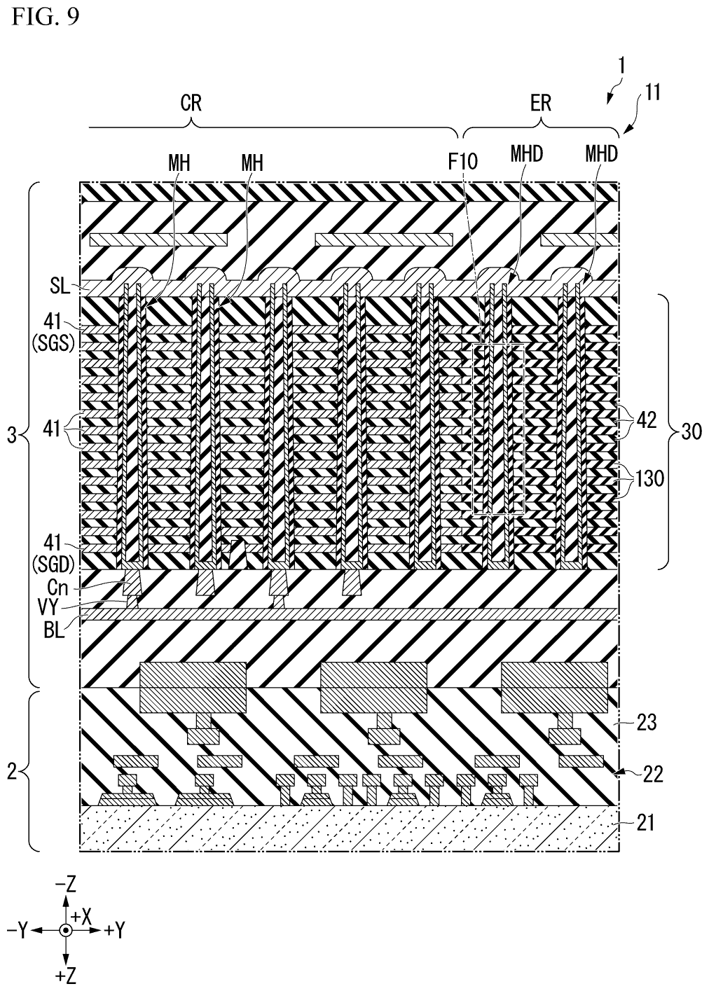

FIG. 8 is a cross-sectional view along line F8-F8 of the semiconductor storage device 1 shown in FIG. 6. As shown in FIG. 6, the fifth boundary B5 in the X direction is present at the boundary between the word line WLA-2 and the insulating layer 42A-1. As shown in FIG. 8, when viewed from the Z direction, an annular fourth boundary line BD4 is defined by an annular edge EC4 of the word line WLA-2 at the fifth boundary B5 (see FIG. 6). The fourth boundary line BD4 is defined between the word line WLA-2 and the memory pillar MH.

Similarly, as shown in FIG. 6, the fourth boundary B4 in the X direction is present at the boundary between the word line WLA-1 and the insulating layer 42A-1. As shown in FIG. 8, when viewed from the Z direction, an annular third boundary line BD3 is defined by an annular edge EC3 of the word line WLA-1 at the fourth boundary B4 (see FIG. 6). The third boundary line BD3 is defined between the word line WLA-1 and the memory pillar MH.

When viewed from the Z direction, the third boundary line BD3 is positioned inside the fourth boundary line BD4.

This relationship is also satisfied between the other two word lines WLA included in the first multi-layered body 31. For example, the above-described relationship is also satisfied between the word line WLA-2 and the word line WLA-3. In this case, in the above description regarding the word line WLA-1 and the word line WLA-2, the “word line WLA-1” need only be read as the “word line WLA-2”, the “word line WLA-2” need only be read as the “word line WLA-3”, and the “insulating layer 42A-1” need only be read as the “insulating layer 42A-2”.

### <6. Configuration of End Part Region>

Next, an end part region ER of the memory cell array 11 will be described.

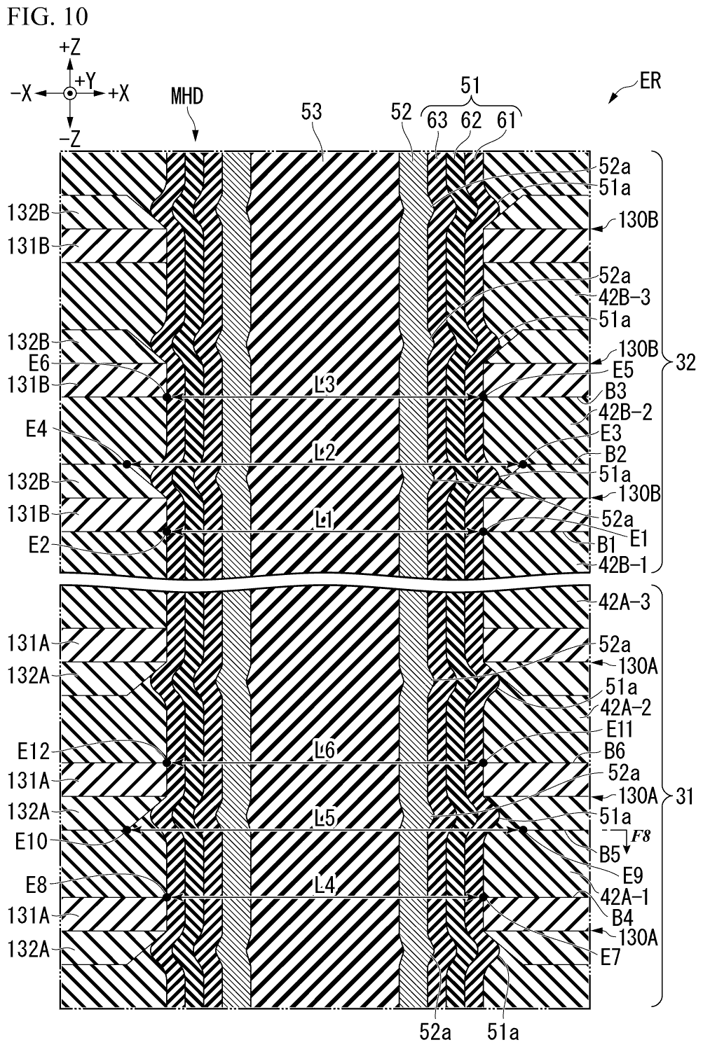

FIG. 9 is a cross-sectional view along line F9-F9 of the semiconductor storage device 1 shown in FIG. 3. The multi-layered body 30 has a memory region CR and the end part region ER.

The memory region CR includes the above-described plurality of conductive layers 41 and plurality of insulating layers 42. The plurality of conductive layers 41 and the plurality of insulating layers 42 are alternately stacked one by one in the Z direction. The plurality of conductive layers 41 are formed by performing a replacement process in which a sacrificial layer (an insulating layer 130 to be described later) provided during manufacturing is replaced with the conductive layer 41.

On the other hand, the end part region ER includes a plurality of insulating layers 130 instead of the plurality of conductive layers 41. That is, the end part region ER includes the plurality of insulating layers 130 and the plurality of insulating layers 42. The plurality of insulating layers 130 and the plurality of insulating layers 42 are alternately stacked one by one in the Z direction. The insulating layer 130, due to its presence in the end part region ER, is an insulating layer that has remained in the multi-layered body 30 without being replaced by the conductive layer 41 during the replacement process. Note that, a plurality of dummy memory pillars MHD are provided in the end part region ER. The dummy memory pillar MHD has the same configuration as the memory pillar MH, but is a columnar body that is not used for storing data.

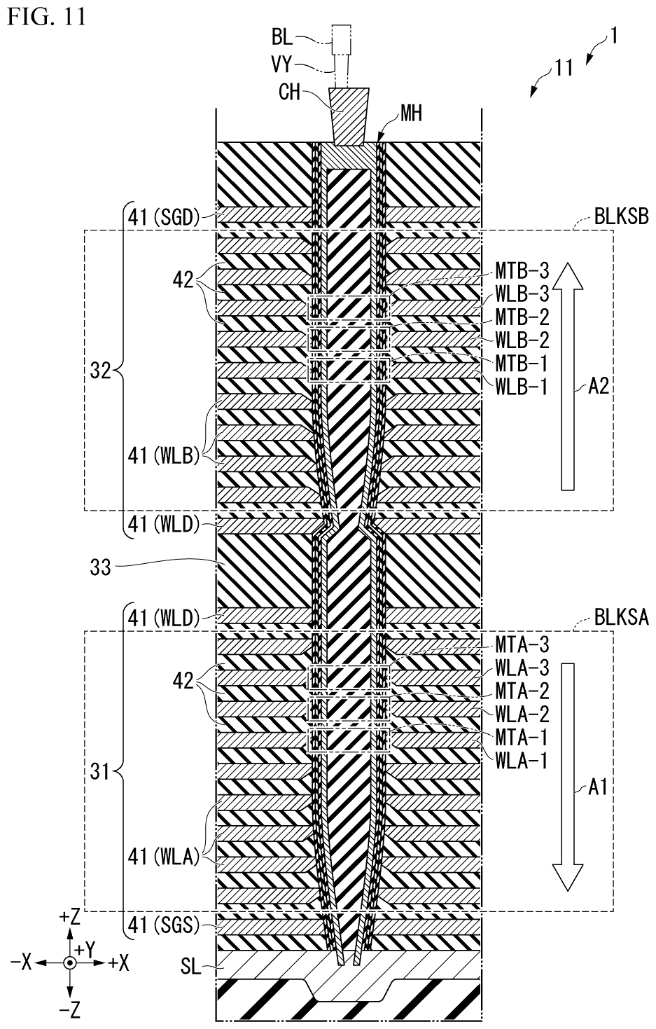

FIG. 10 is an enlarged cross-sectional view showing a region surrounded by line F10 of the semiconductor storage device 1 shown in FIG. 9.

### (Structure of Second Multi-Layered Body)

First, a structure of the second multi-layered body 32 will be described. The second multi-layered body 32 includes a plurality of insulating layers 130B as the plurality of insulating layers 130. The insulating layers 130B each include an insulating layer 131B and an insulating layer 132B.

The insulating layer 131B is included in the insulating layer 130B, for example, between a center of the insulating layer 130B in the Z direction and a surface of the insulating layer 130B on the side in the −Z direction. The insulating layer 131B may have the same thickness and the same shape as the base portion 101 of the word line WLB. The insulating layer 131B contains a first material. One example of the first material includes nitrogen and silicon (for example, silicon nitride (SiN)).

The insulating layer 132B is positioned on the side in the +Z direction with respect to the insulating layer 131B. The insulating layer 132B is included in the insulating layer 130B, for example, between the center of the insulating layer 130B in the Z direction and a surface of the insulating layer 130B on the side in the +Z direction. At least a part of the insulating layer 132B is retracted with respect to the insulating layer 131B to become further away from the dummy memory pillar MHD in the X direction. For example, the insulating layer 132B is inclined to become further away from the dummy memory pillar MHD as it is positioned farther in on the side in the +Z direction. The insulating layer 132B may have the same thickness and the same shape as the retracted portion 102 of the word line WLB. The insulating layer 132B contains a second material. The second material has a different composition from the first material. The second material is a material that is more easily removed by a first etchant than the first material (for example, a material that has a different wet etching rate with respect to the first etchant). An example of the second material includes nitrogen and silicon, and has a higher oxygen content than the above-described first material (for example, oxygen-doped silicon nitride (SiN)).

A presence of the two insulating layers, the insulating layer 131B and the insulating layer 132B, can be ascertained, for example, by the following method.

(1) Observing an interface between the insulating layer 131B and the insulating layer 132B using a transmission electron microscope (TEM).

(2) Detecting a difference in component (for example, an oxygen concentration) between the insulating layer 131B and the insulating layer 132B through a component analysis.

Such a method is also applicable to a method of ascertaining a presence of an insulating layer 131A and an insulating layer 132A to be described later.

### (Structure of First Multi-Layered Body)

Next, a structure of the first multi-layered body 31 will be described. The first multi-layered body 31 includes a plurality of insulating layers 130A as the plurality of insulating layers 130. The insulating layers 130A each include the insulating layer 131A and the insulating layer 132A.

The insulating layer 131A is included in the insulating layer 130A, for example, between a center of the insulating layer 130A in the Z direction and a surface of the insulating layer 130A on the side in the +Z direction. The insulating layer 131A may have the same thickness and the same shape as the base portion 111 of the word line WLA. The insulating layer 131A contains the first material described above.

The insulating layer 132A is positioned on the side in the −Z direction with respect to the insulating layer 131A. The insulating layer 132A is included in the insulating layer 130A, for example, between the center of the insulating layer 130A in the Z direction and a surface of the insulating layer 130A on the side in the −Z direction. At least a part of the insulating layer 132A is retracted with respect to the insulating layer 131A to become further away from the dummy memory pillar MHD in the X direction. For example, the insulating layer 132A is inclined to become further away from the dummy memory pillar MHD as it is positioned farther in the side in the −Z direction.

The insulating layer 132A may have the same thickness and the same shape as the retracted portion 112 of the word line WLA. The insulating layer 132A contains the second material described above.

### <7. Control Method>

Next, a control method of the semiconductor storage device 1 will be described. Note that, the control method described below is executed by, for example, the control circuit 14.

### <7.1 Write Order>

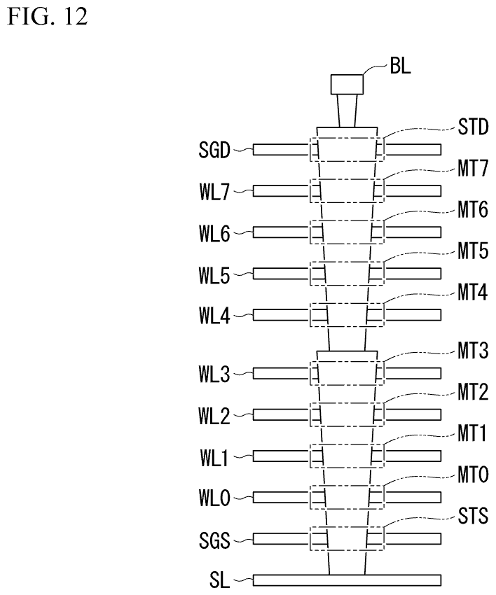

FIG. 11 is a view showing a write order according to the first embodiment. As shown in FIG. 11, writing of data to the first sub-block BLKSA is performed by applying a program voltage Vpgm for data writing to the plurality of word lines WLA of the first multi-layered body 31, starting to apply from the word line WLA positioned on an uppermost side and sequentially moving to apply to each subsequent word line WLA positioned below (see arrow A1 in the drawing).

On the other hand, writing of data to the second sub-block BLKSB is performed by applying the program voltage Vpgm for data writing to the plurality of word lines WLB of the second multi-layered body 32, starting to apply from the word line WLB positioned on a lowermost side and then sequentially moving to apply to each subsequent word line WLB positioned above (see arrow A2 in the drawing).

Note that, in the present application, “applying a program voltage” means, for example, repeating a program loop including an application operation of the program voltage Vpgm, a program verification for determining whether or not a threshold voltage of the memory cell transistor MT to be written has reached a threshold voltage corresponding to desired data when the program voltage Vpgm is applied, and a voltage change operation for increasing a set value of the program voltage Vpgm when the above-described program verification does not pass, until a predetermined condition is satisfied.

In the present embodiment, a memory cell transistor MTA-1 is formed at a portion in which the word line WLA-1 and the memory pillar MH intersect. A memory cell transistor MTA-2 is formed at a portion in which the word line WLA-2 and the memory pillar MH intersect. A memory cell transistor MTA-3 is formed at a portion in which the word line WLA-3 and the memory pillar MH intersect. The memory cell transistor MTA-1 is an example of a “third memory cell transistor”. The memory cell transistor MTA-2 is an example of a “fourth memory cell transistor”.

The memory cell transistors MTA-1 to MTA-3 are aligned in the −Z direction in order of the memory cell transistor MTA-3, the memory cell transistor MTA-2, and the memory cell transistor MTA-1. In this case, the control circuit 14 performs a write operation that injects charge into the memory cell transistor MTA-3, then performs a write operation that injects charge into the memory cell transistor MTA-2, and then performs a write operation that injects charge into the memory cell transistor MTA-1.

On the other hand, a memory cell transistor MTB-1 is formed at a portion in which the word line WLB-1 and the memory pillar MH intersect. A memory cell transistor MTB-2 is formed at a portion in which the word line WLB-2 and the memory pillar MH intersect. A memory cell transistor MTB-3 is formed at a portion in which the word line WLB-3 and the memory pillar MH intersect. The memory cell transistor MTB-1 is an example of a “first memory cell transistor”. The memory cell transistor MTB-2 is an example of a “second memory cell transistor”.

The memory cell transistors MTB-1 to MTB-3 are aligned in the −Z direction in order of the memory cell transistor MTB-3, the memory cell transistor MTB-2, and the memory cell transistor MTB-1. In this case, the control circuit 14 performs a write operation that injects charge into the memory cell transistor MTB-1, then performs a write operation that injects charge into the memory cell transistor MTB-2, and then performs a write operation that injects charge into the memory cell transistor MTB-3.

### <7.2 Voltage Management of Channel Layer>

Here, a voltage management of the channel layer 52 will be described. If a potential of the channel layer 52 drops to a negative potential for some reason before a write operation is performed, there is a likelihood that a voltage of the channel layer 52 will not rise sufficiently during the write operation, and a large potential difference will occur when the program voltage Vpgm is applied, causing a threshold voltage of the memory cell transistors MT, which are not intended to be written, to rise. Therefore, the control circuit 14 of the present embodiment performs a channel pre-charge in which a voltage of the channel layer 52 is reset to 0 V before the write operation is performed.

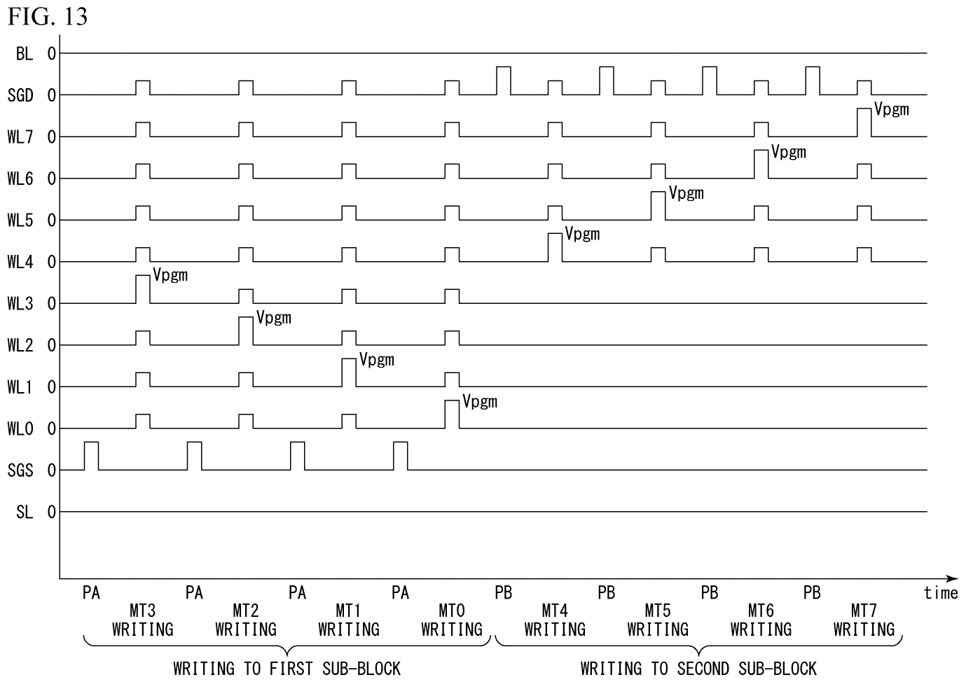

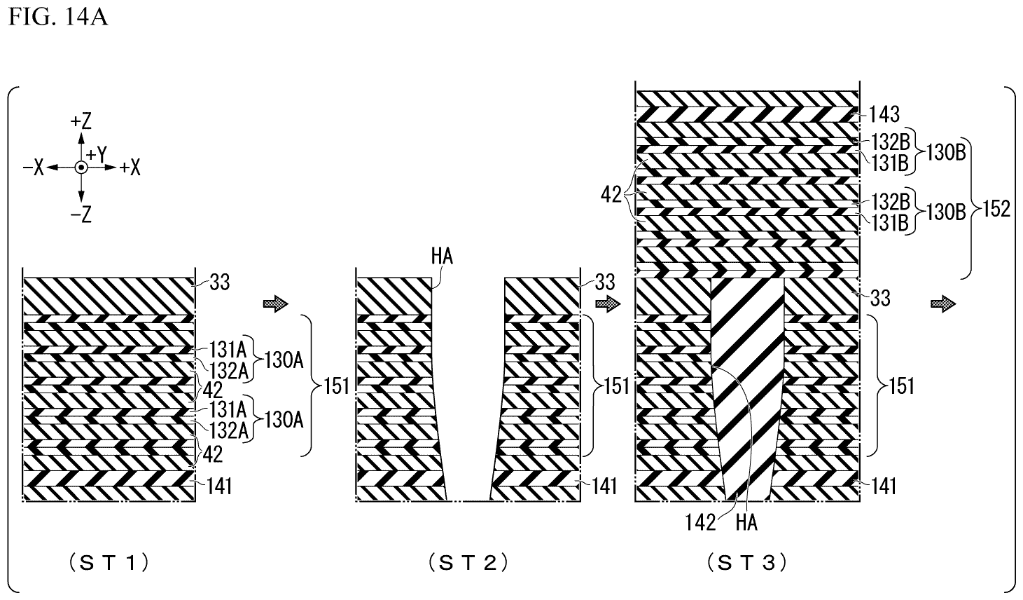

FIG. 12 is a view schematically showing the memory pillar MH. FIG. 13 is a timing chart for explaining a write operation related to the memory pillar MH shown in FIG. 12. In FIG. 13, among voltages applied to the word line WL, a voltage denoted by “Vpgm” means the above-described program voltage Vpgm. On the other hand, among voltages applied to the word line WL, voltages between 0 and Vpgm that are not denoted by “Vpgm” mean voltages that are high enough to turn the memory cell transistor MT to an ON state, but are yet low enough not to cause writing.

As shown in FIG. 13, when writing to the first multi-layered body 31 (writing to the first sub-block BLKSA), before the write operation to each memory cell transistor MT is performed, a voltage is applied to the source-side selection gate line SGS so that the channel layer 52 and the source line SL are electrically connected and a channel pre-charge PA is performed to set the voltage of the channel layer 52 to 0 V. Therefore, when writing to the first multi-layered body 31 (writing to the first sub-block BLKSA), the channel pre-charge PA is performed using the source-side selection gate line SGS, and then the write operation is performed in order of the memory cell transistor MT3, the memory cell transistor MT2, the memory cell transistor MT1, and the memory cell transistor MT0.

On the other hand, when writing to the second multi-layered body 32 (writing to the second sub-block BLKSB), the first multi-layered body 31 (the first sub-block BLKSA) is already in a written state, and it is difficult to perform the channel pre-charge PA using the source-side selection gate line SGS. Therefore, when writing to the second multi-layered body 32 (writing to the second sub-block BLKSB), before the write operation to each memory cell transistor MT is performed, a voltage is applied to the drain-side selection gate line SGD so that the channel layer 52 and the bit line BL are electrically connected and a channel pre-charge PB is performed to set the voltage of the channel layer 52 to 0 V. Therefore, when writing to the second multi-layered body 32 (writing to the second sub-block BLKSB), the channel pre-charge PB is performed using the drain-side selection gate line SGD, and then the write operation is performed in order of the memory cell transistor MT4, the memory cell transistor MT5, the memory cell transistor MT6, and the memory cell transistor MT7.

### <8. Manufacturing Method>

Next, a manufacturing method of the semiconductor storage device 1 will be described.

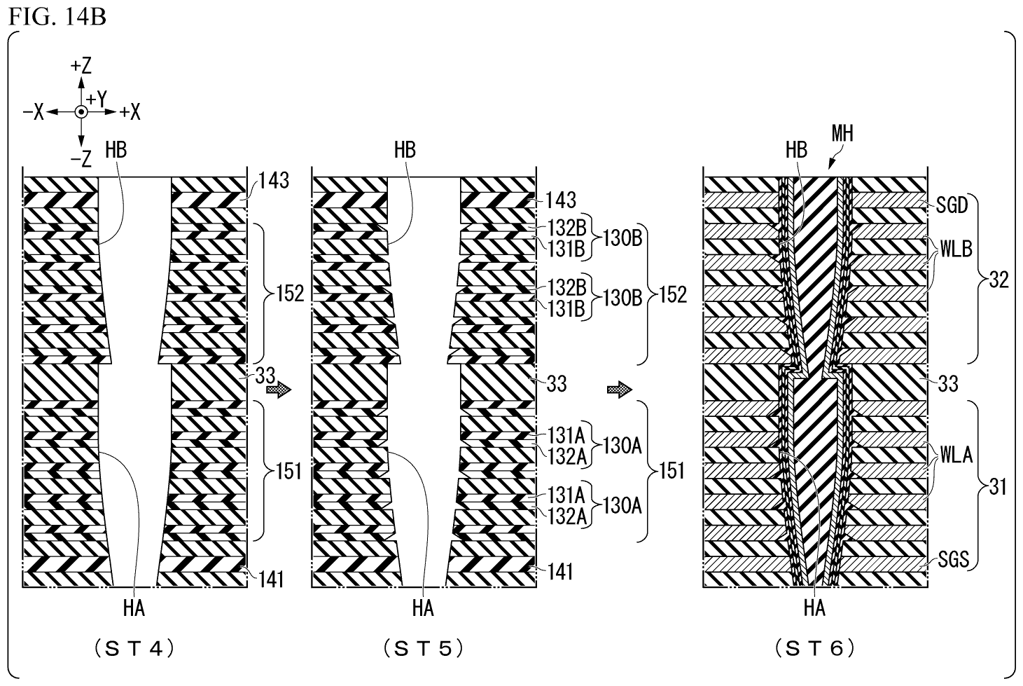

FIGS. 14A and 14B are cross-sectional views for explaining a manufacturing method of the semiconductor storage device 1. Note that, in the following description, for convenience of explanation, illustration relating to a manufacturing process of the dummy word line WLD will be omitted. Also, in the following description, a manufacturing process for the plurality of word lines WL will be mainly described. Processes other than those described below can be performed by known technologies.

First, the insulating layer 141 is formed on the insulating layer 42. The insulating layer 141 is a sacrificial layer that is replaced with the source-side selection gate line SGS in a replacement process to be described later. Next, a multi-layered body 151 is formed on top of the insulating layer 141. The multi-layered body 151 is formed by repeatedly stacking the insulating layer 132A, the insulating layer 131A, and the insulating layer 42 in order of the insulating layer 132A, the insulating layer 131A, and the insulating layer 42 in the Z direction. Next, the intermediate insulating layer 33 is stacked on top of the multi-layered body 151 (see ST1 in FIG. 14A).

Next, a hole HA penetrating the intermediate insulating layer 33, the multi-layered body 151, and the insulating layer 141 in the Z direction is formed (see ST2 in FIG. 14A). Next, the inside of the hole HA is filled with an insulating portion 142. Next, a multi-layered body 152 is formed on top of the intermediate insulating layer 33. The multi-layered body 152 is formed by repeatedly stacking the insulating layer 131B, the insulating layer 132B, and the insulating layer 42 in order of the insulating layer 131B, the insulating layer 132B, and the insulating layer 42 in the Z direction. The insulating layer 131B is an example of a “first layer”. The insulating layer 132B is an example of a “second layer”. The insulating layer 42 is an example of a “third layer”. Next, an insulating layer 143 is formed on top of the multi-layered body 152. The insulating layer 143 is a sacrificial layer that is replaced with the drain-side selection gate line SGD in the replacement process to be described later (see ST3 in FIG. 14A).

Next, a hole HB penetrating the insulating layer 143 and the multi-layered body 152 in the Z direction is formed. Next, the insulating portion 142 in the hole HA is removed by etching through the hole HB (see ST4 in FIG. 14B). Next, the first etchant is supplied to the inside of the hole HA and the hole HB to perform etching (for example, wet etching). At this time, the second material contained in the insulating layer 132A and the insulating layer 132B is more easily removed by the first etchant than the first material contained in the insulating layer 131A and the insulating layer 131B. Therefore, the insulating layer 132A is largely removed compared to the insulating layer 131A and retracts in a direction away from the hole HA with respect to the insulating layer 131A. Therefore, a step is formed between the insulating layer 132A and the insulating layer 42. Similarly, the insulating layer 132B is largely removed compared to the insulating layer 131B and retracts in a direction away from the hole HB with respect to the insulating layer 131B. Therefore, a step is formed between the insulating layer 132B and the insulating layer 42 (see ST5 in FIG. 14B).

Next, the memory pillar MH is formed inside the hole HA and the hole HB. That is, the memory pillar MH is formed by sequentially supplying materials of the memory film 51, the channel layer 52, and the insulating core 53 to the inside of the hole HA and the hole HB.

Next, the replacement process is performed. That is, the insulating layer 131A, the insulating layer 131B, the insulating layer 132A, the insulating layer 132B, the insulating layer 141, and the insulating layer 143 are removed by etching through grooves (not shown in the drawings). Then, the word line WLA is formed by supplying a conductive material into a space in which the insulating layer 131A and the insulating layer 132A have been removed. Similarly, the word line WLB is formed by supplying a conductive material into a space in which the insulating layer 131B and the insulating layer 132B have been removed. The source-side selection gate line SGS is formed by supplying a conductive material into a space in which the insulating layer 141 has been removed. The drain-side selection gate line SGD is formed by supplying a conductive material into a space in which the insulating layer 143 has been removed (see ST6 in FIG. 14B). Therefore, the manufacturing process for the plurality of word lines WL is completed.

### <9. Operation>

Next, an operation of the semiconductor storage device 1 will be described.

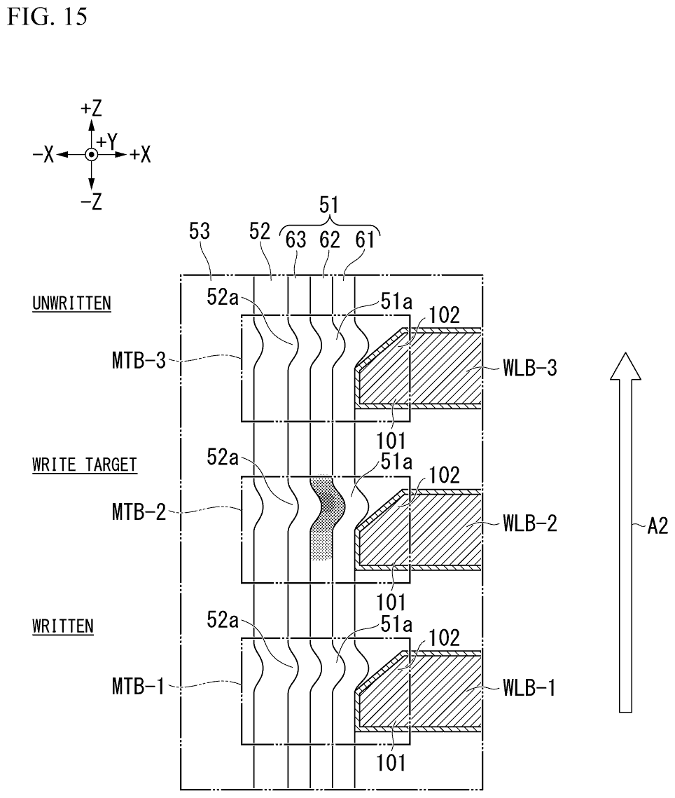

FIG. 15 is a cross-sectional view for explaining an operation of the semiconductor storage device 1. Here, the word line WLB is taken as an example to explain an effect thereof.

As shown in FIG. 15, the word line WLB has the base portion 101 and the retracted portion 102 positioned on the side in the +Z direction of the base portion 101. Here, it is ascertained from the research by the present invertor that, in the memory cell transistor MTB (for example, the memory cell transistor MTB-2) to be written that is connected to the word line WLB having the retracted portion 102, charge is concentrated and accumulated in a region on the side in the +Z direction of a center of the memory cell transistor MTB in the Z direction.

Therefore, when the retracted portion 102 is provided in the word line WLB, a region in which charge is concentrated and accumulated in the memory cell transistor MTB-2 can be biased toward on the side in the +Z direction to be away from the written memory cell transistor MTB (for example, the memory cell transistor MTB-1) with respect to the center of the memory cell transistor MTB-2 in the Z direction. As a result, an influence of the write operation to the memory cell transistor MTB-2 on the written memory cell transistor MTB-1 (an influence of so-called adjacent interference) is reduced. Therefore, electrical characteristics of the semiconductor storage device 1 are improved. The same applies to the word line WLA having the retracted portion 112.

### Second Embodiment

Next, a second embodiment will be described. The second embodiment differs from the first embodiment in that the memory pillar MH includes three columnar portions 71, 72, and 73. Note that, configurations other than those described below are the same as the configurations of the first embodiment.

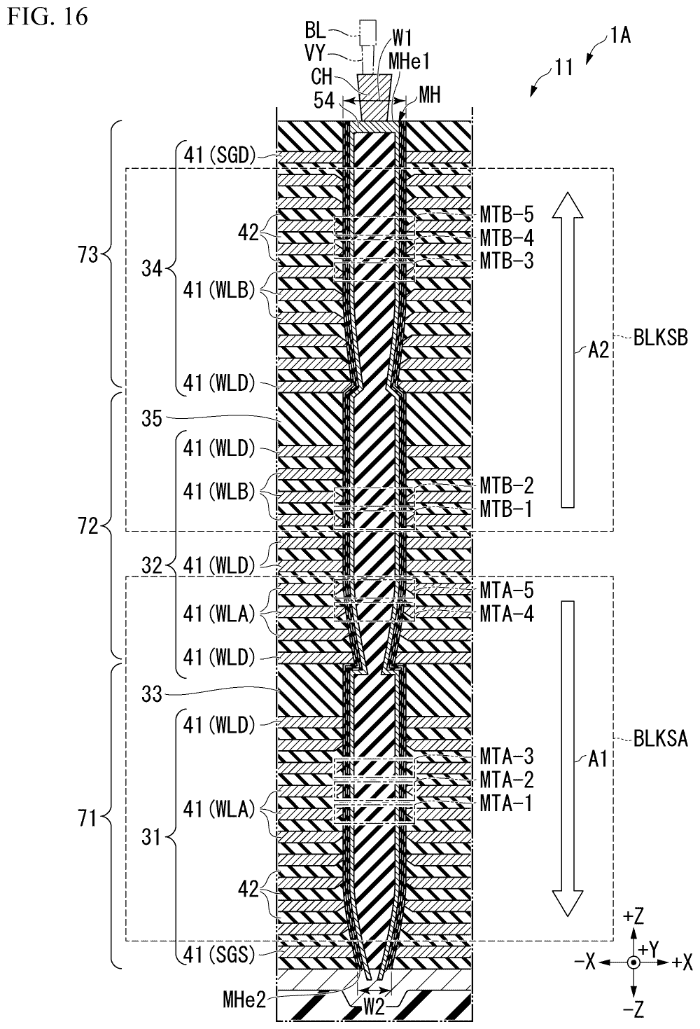

FIG. 16 is a cross-sectional view showing a semiconductor storage device 1A according to the second embodiment. In the present embodiment, a multi-layered body 30 includes a first multi-layered body 31, a second multi-layered body 32, an intermediate insulating layer 33, a third multi-layered body 34, and an intermediate insulating layer 35.

The second multi-layered body 32 is disposed on the side in the +Z direction with respect to the first multi-layered body 31. The intermediate insulating layer 33 is disposed between the first multi-layered body 31 and the second multi-layered body 32 in the Z direction. The third multi-layered body 34 is disposed on the side in the +Z direction with respect to the second multi-layered body 32. The intermediate insulating layer 35 is disposed between the second multi-layered body 32 and the third multi-layered body 34 in the Z direction. A thickness of the intermediate insulating layer 35 in the Z direction is larger than the thickness of an insulating layer 42 in the Z direction. The intermediate insulating layer 35 contains, for example, silicon and oxygen.

The first multi-layered body 31, the second multi-layered body 32, and the third multi-layered body 34 each include a plurality of conductive layers 41 and a plurality of insulating layers 42. In each of the first multi-layered body 31, the second multi-layered body 32, and the third multi-layered body 34, the plurality of conductive layers 41 and the plurality of insulating layers 42 are alternately stacked one by one in the Z direction.

In the present embodiment, word lines WL included in the first multi-layered body 31 and word lines WL included in a lower half of the second multi-layered body 32 are word lines WLA. On the other hand, word lines WL included in the third multi-layered body 34 and word lines WL included in an upper half of the second multi-layered body 32 are word lines WLB. The third multi-layered body 34 has one or more dummy word lines WLD between the word line WLA and the word line WLB.

Each memory pillar MH is, for example, a three-stage columnar body in the Z direction and includes the first columnar portion 71, the second columnar portion 72, and the third columnar portion 73. The first columnar portion 71 is provided in the first multi-layered body 31 and the intermediate insulating layer 33. The second columnar portion 72 is provided in the second multi-layered body 32 and the intermediate insulating layer 35. The third columnar portion 73 is provided in the third multi-layered body 34. A diameter of each of the first columnar portion 71, the second columnar portion 72, and the third columnar portion 73 gradually decreases in the −Z direction. In other words, a width in the X direction of each of the first columnar portion 71, the second columnar portion 72, and the third columnar portion 73 gradually decreases in the −Z direction.

In the present embodiment, a plurality of memory cell transistors MTA are formed at intersections between a plurality of word lines WLA and the memory pillar MH. The plurality of memory cell transistors MTA include memory cell transistors MTA-1, MTA-2, and MTA-3 formed at intersections of the first multi-layered body 31 and the first columnar portion 71, and memory cell transistors MTA-4 and MTA-5 formed at intersections of the second multi-layered body 32 and the second columnar portion 72. These are aligned in the −Z direction in order of the memory cell transistor MTA-5, the memory cell transistor MTA-4, the memory cell transistor MTA-3, the memory cell transistor MTA-2, and the memory cell transistor MTA-1.

Similarly, a plurality of memory cell transistors MTB are formed at intersections between a plurality of word lines WLB and the memory pillar MH. The plurality of memory cell transistors MTB include memory cell transistors MTB-1 and MTB-2 formed at intersections of the second multi-layered body 32 and the second columnar portion 72, and memory cell transistors MTB-3, MTB-4, and MTB-5 formed at intersection of the third multi-layered body 34 and the third columnar portion 73. These are aligned in the −Z direction in order of the memory cell transistor MTB-5, the memory cell transistor MTB-4, the memory cell transistor MTB-3, the memory cell transistor MTB-2, and the memory cell transistor MTB-1.

In the present embodiment, writing of data to a first sub-block BLKSA is performed by applying a program voltage Vprg to the word lines WL (word lines WLA) corresponding to the first sub-block BLKSA, starting to apply from the word line WLA positioned on an uppermost side and sequentially moving to apply to each subsequent word line WLA positioned below. For example, a control circuit 14 performs a write operation that injects charge into the memory cell transistor MTA-5, then performs a write operation that injects charge into the memory cell transistor MTA-4, then performs a write operation that injects charge into the memory cell transistor MTA-3, then performs a write operation that injects charge into the memory cell transistor MTA-2, and then performs a write operation that injects charge into the memory cell transistor MTA-1.

On the other hand, writing of data to a second sub-block BLKSB is performed by applying a program voltage Vprg to the word lines WL (word lines WLB) corresponding to the second sub-block BLKSB, starting to apply from the word line WLB positioned on a lowermost side and sequentially moving to apply to each subsequent word line WLB positioned above. For example, the control circuit 14 performs a write operation that injects charge into the memory cell transistor MTB-1, then performs a write operation that injects charge into the memory cell transistor MTB-2, then performs a write operation that injects charge into the memory cell transistor MTB-3, then performs a write operation that injects charge into the memory cell transistor MTB-4, and then performs a write operation that injects charge into the memory cell transistor MTB-5.

According to such a configuration, it is possible to provide the semiconductor storage device 1A in which improvement in electrical characteristics can be achieved as in the first embodiment.

### Third Embodiment

Next, a third embodiment will be described. The third embodiment differs from the first embodiment in that the word line WL included in the first multi-layered body 31 is a word line WLA′. Note that, configurations other than those described below are the same as the configurations of the first embodiment.

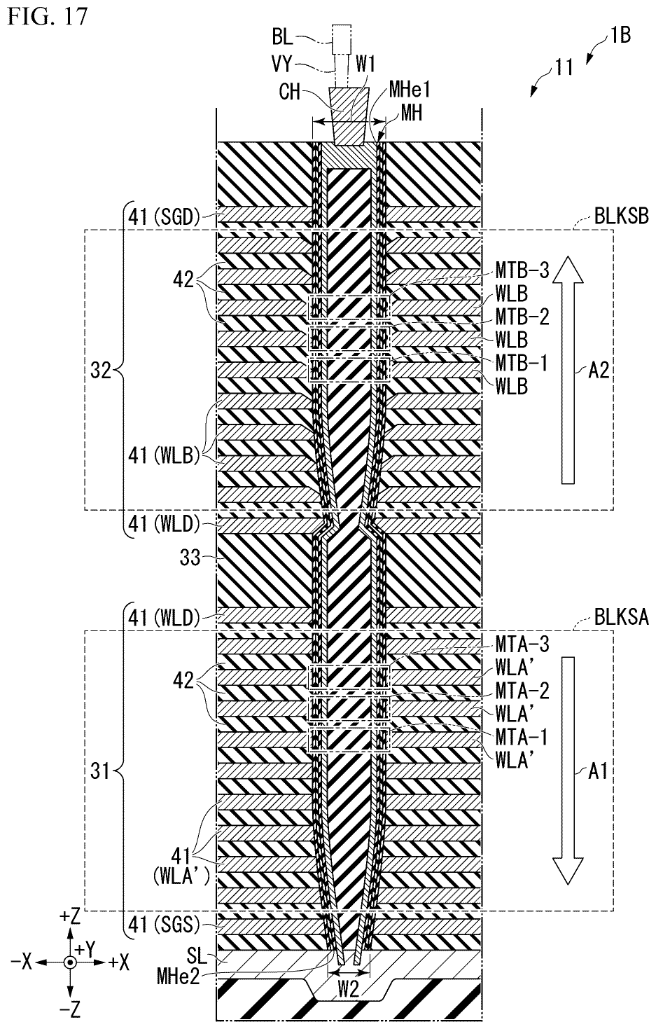

FIG. 17 is a cross-sectional view showing a semiconductor storage device 1B according to the third embodiment. In the present embodiment, the word line WL included in the first multi-layered body 31 (a word line corresponding to a first sub-block BLKSA) is the word line WLA′. The word line WLA′ is a word line WL that does not have the retracted portion 112. An operation of a control circuit 14 is the same as that in the first embodiment. Even with such a configuration, it is possible to provide the semiconductor storage device 1B in which improvement in electrical characteristics for, for example, at least a word line WLB can be achieved.

### Fourth Embodiment

Next, a fourth embodiment will be described. The fourth embodiment differs from the first embodiment in that the word line WL included in the first multi-layered body 31 is a word line WLB. Note that, configurations other than those described below are the same as the configurations of the first embodiment.

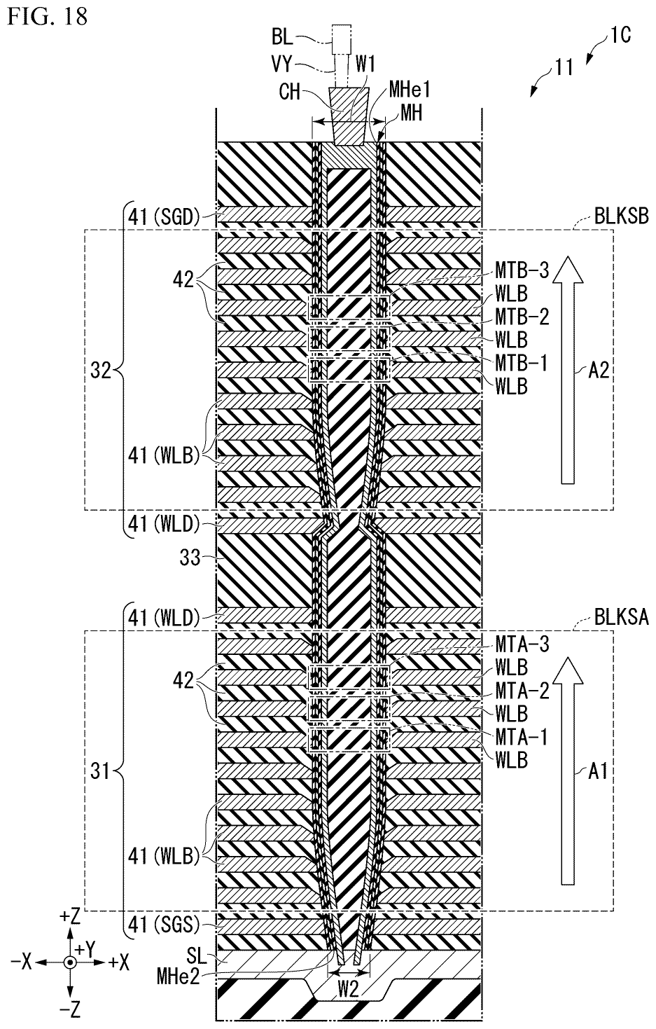

FIG. 18 is a cross-sectional view showing a semiconductor storage device 1C according to the fourth embodiment. In the present embodiment, the word line WL included in the first multi-layered body 31 is the word line WLB. Writing of data to a first sub-block BLKSA is performed by applying a program voltage Vprg to the word lines WL (word lines WLB) corresponding to the first sub-block BLKSA, starting to apply from the word line WLB positioned on a lowermost side and sequentially moving to apply to each subsequent word line WLB positioned above. For example, a control circuit 14 performs a write operation that injects charge into a memory cell transistor MTA-1, then performs a write operation that injects charge into a memory cell transistor MTA-2, and then performs a write operation that injects charge into a memory cell transistor MTA-3. According to such a configuration, it is possible to provide the semiconductor storage device 1C in which improvement in electrical characteristics can be achieved.

### Fifth Embodiment

Next, a fifth embodiment will be described. The fifth embodiment differs from the first embodiment in that the word line WL included in the second multi-layered body 32 is a word line WLA. Note that, configurations other than those described below are the same as the configurations of the first embodiment.

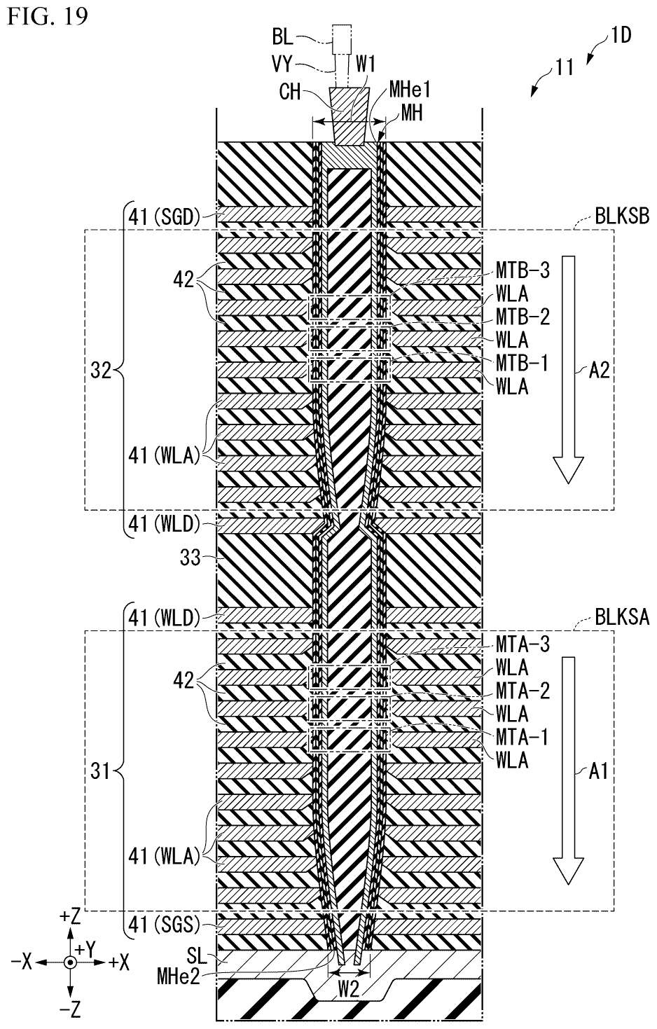

FIG. 19 is a cross-sectional view showing a semiconductor storage device 1D according to the fifth embodiment. The word line WL included in the second multi-layered body 32 is the word line WLA. In the present embodiment, the side in the −Z direction is an example of a “first side”. On the side in the +Z direction is an example of a “second side”. A word line WLA-1 is an example of a “first gate electrode layer”. A word line WLA-2 is an example of a “second gate electrode layer”. A seventh edge E7, an eighth edge E8, a ninth edge E9, a tenth edge E10, an eleventh edge E11, and a twelfth edge E12 are respectively examples of a “first edge”, a “second edge”, a “third edge”, a “fourth edge”, a “fifth edge”, and a “sixth edge”. A fourth distance L4, a fifth distance L5, and a sixth distance L6 are respectively examples of a “first distance”, a “second distance”, and a “third distance”.

Writing of data to a second sub-block BLKSB is performed by applying a program voltage Vprg to the word lines WL (word lines WLA) corresponding to the second sub-block BLKSB, starting to apply from the word line WLA positioned on an uppermost side and sequentially moving to apply to each subsequent word line WLA positioned below. For example, a control circuit 14 performs a write operation that injects charge into a memory cell transistor MTB-3, then performs a write operation that injects charge into a memory cell transistor MTB-2, and then performs a write operation that injects charge into a memory cell transistor MTB-1. According to such a configuration, it is possible to provide the semiconductor storage device 1D in which improvement in electrical characteristics can be achieved.

While some embodiments have been described, the embodiments are not limited to the above-described examples. For example, some embodiments described above may be realized in combination with each other.

According to at least one of the embodiments described above, a semiconductor storage device includes a multi-layered body and a columnar body. A distance between a first edge of a first gate electrode layer adjacent to the columnar body and a second edge of the first gate electrode layer adjacent to the columnar body from a side opposite to the first edge at a boundary between the first gate electrode layer and a first insulating layer is defined as a first distance. A distance between a third edge of the first gate electrode layer adjacent to the columnar body and a fourth edge of the first gate electrode layer adjacent to the columnar body from a side opposite to the third edge at a boundary between the first gate electrode layer and a second insulating layer is defined as a second distance. A distance between a fifth edge of a second gate electrode layer adjacent to the columnar body and a sixth edge of the second gate electrode layer adjacent to the columnar body from a side opposite to the fifth edge at a boundary between the second gate electrode layer and the second insulating layer is defined as a third distance. The second distance is larger than the first distance and larger than the third distance. According to such a configuration, improvement in electrical characteristics can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a multi-layered body including a plurality of gate electrode layers and a plurality of insulating layers, the plurality of gate electrode layers and the plurality of insulating layers being alternately stacked one by one in a first direction; and
a columnar body extending in the first direction within the multi-layered body, the columnar body including a memory film and a channel layer, wherein
the plurality of gate electrode layers include a first gate electrode layer and a second gate electrode layer, the second gate electrode layer being on a first side in the first direction with respect to the first gate electrode layer, the second gate electrode layer being adjacent to the first gate electrode layer among the plurality of gate electrode layers,
the plurality of insulating layers include a first insulating layer and a second insulating layer, the first insulating layer being adjacent to the first gate electrode layer from a second side opposite to the first side in the first direction, the second insulating layer being between the first gate electrode layer and the second gate electrode layer, and
when a direction orthogonal to the first direction is defined as a second direction, when viewed in a cross section in the first direction and the second direction,
a first boundary is between the first gate electrode layer and the first insulating layer,
the first boundary extends in the second direction,
a second boundary is between the first gate electrode layer and the second insulating layer,
the second boundary extends in the second direction,
a third boundary is between the second gate electrode layer and the second insulating layer,
the third boundary extends in the second direction,
the first gate electrode layer has a first edge adjacent to the columnar body at the first boundary,
the first gate electrode layer has a second edge adjacent to the columnar body from a side opposite to the first edge at the first boundary,
a distance between the first edge and the second edge is defined as a first distance,
the first gate electrode layer has a third edge adjacent to the columnar body at the second boundary,
the first gate electrode layer has a fourth edge adjacent to the columnar body from a side opposite to the third edge at the second boundary,
a distance between the third edge and the fourth edge is defined as a second distance,
the second gate electrode layer has a fifth edge adjacent to the columnar body at the third boundary,
the second gate electrode layer has a sixth edge adjacent to the columnar body from a side opposite to the fifth edge at the third boundary,
a distance between the fifth edge and the sixth edge is defined as a third distance, and
the second distance is larger than the first distance and larger than the third distance.

2. The semiconductor storage device according to claim 1, wherein
when viewed from the first direction,
a second boundary line is inside a first boundary line,
the first boundary line is annular between the first gate electrode layer and the columnar body by an edge of the first gate electrode layer at the second boundary, and
the second boundary line is annular between the second gate electrode layer and the columnar body by an edge of the second gate electrode layer at the third boundary.

3. The semiconductor storage device according to claim 1, wherein
the first gate electrode layer includes a first portion and a second portion,
the second portion is on the first side with respect to the first portion,
the first portion includes a first edge part adjacent to the columnar body,
the second portion includes a second edge part adjacent to the columnar body,
the second edge part is more greatly inclined with respect to the first direction compared to the first edge part,
the second gate electrode layer includes a third portion and a fourth portion,
the fourth portion is on the first side with respect to the third portion,
the third portion includes a third edge part adjacent to the columnar body,
the fourth portion includes a fourth edge part adjacent to the columnar body, and
the fourth edge part is more greatly inclined with respect to the first direction compared to the third edge part.

4. The semiconductor storage device according to claim 1, wherein
a shortest distance between the channel layer and the third edge of the first gate electrode layer is larger than a shortest distance between the channel layer and the first edge of the first gate electrode layer.

5. The semiconductor storage device according to claim 1, wherein
a width in the second direction of an end of the columnar body on the first side is larger than a width in the second direction of an end of the columnar body on the second side, and
the third edge and the fourth edge are on the first side with respect to the first edge and the second edge.

6. The semiconductor storage device according to claim 1, wherein
a width in the second direction of an end of the columnar body on the second side is larger than a width in the second direction of an end of the columnar body on the first side, and
the third edge and the fourth edge are on the first side with respect to the first edge and the second edge.

7. The semiconductor storage device according to claim 1, further comprising:
a control circuit;
a first memory cell transistor at a portion in which the first gate electrode layer and the columnar body intersect; and
a second memory cell transistor at a portion in which the second gate electrode layer and the columnar body intersect, wherein
the control circuit is configured to control the first memory cell transistor and the second memory cell transistor to perform a second write operation after a first write operation,
the first write operation includes an operation of injecting charge into the first memory cell transistor when writing data, and
the second write operation includes an operation of injecting charge into the second memory cell transistor when writing data.

8. The semiconductor storage device according to claim 1, wherein
the plurality of gate electrode layers include a third gate electrode layer and a fourth gate electrode layer,
the third gate electrode layer is on the second side with respect to the first gate electrode layer,
the fourth gate electrode layer is between the first gate electrode layer and the third gate electrode layer
the fourth gate electrode layer is adjacent to the third gate electrode layer among the plurality of gate electrode layers,
the plurality of insulating layers include a third insulating layer and a fourth insulating layer,
the third insulating layer is between the third gate electrode layer and the fourth gate electrode layer,
the fourth insulating layer is adjacent to the fourth gate electrode layer from the first side,
when viewed in a cross section,
a fourth boundary is between the third gate electrode layer and the third insulating layer,
the fourth boundary extends in the second direction,
a fifth boundary is between the fourth gate electrode layer and the third insulating layer,
the fifth boundary extends in the second direction,
a sixth boundary is between the fourth gate electrode layer and the fourth insulating layer,
the sixth boundary extends in the second direction,
the third gate electrode layer has a seventh edge adjacent to the columnar body at the fourth boundary,
the third gate electrode layer has has an eighth edge adjacent to the columnar body from a side opposite to the seventh edge at the fourth boundary,
a distance between the seventh edge and the eighth edge is defined as a fourth distance,
the fourth gate electrode layer has a ninth edge adjacent to the columnar body at the fifth boundary,
the fourth gate electrode layer has a tenth edge adjacent to the columnar body from a side opposite to the ninth edge at the fifth boundary,
a distance between the ninth edge and the tenth edge is defined as a fifth distance,
the fourth gate electrode layer has an eleventh edge adjacent to the columnar body at the sixth boundary,
the fourth gate electrode layer has a twelfth edge adjacent to the columnar body from a side opposite to the eleventh edge at the sixth boundary
a distance between the eleventh edge and the twelfth edge is defined as a sixth distance, and
the fifth distance is larger than the fourth distance and larger than the sixth distance.

9. The semiconductor storage device according to claim 8, further comprising:
a control circuit;
a first memory cell transistor at a portion in which the first gate electrode layer and the columnar body intersect;
a second memory cell transistor at a portion in which the second gate electrode layer and the columnar body intersect;
a third memory cell transistor at a portion in which the third gate electrode layer and the columnar body intersect; and
a fourth memory cell transistor at a portion in which the fourth gate electrode layer and the columnar body intersect, wherein
the control circuit is configured to control the first memory cell transistor, the second memory cell transistor, the third memory cell transistor, and the fourth memory cell transistor to perform a second write operation after a first write operation and perform a third write operation after a fourth write operation,
the first write operation includes an operation of injecting charge into the first memory cell transistor when writing data,
the second write operation includes an operation of injecting charge into the second memory cell transistor when writing data,
the third write operation includes an operation of injecting charge into the third memory cell transistor when writing data, and
the fourth write operation includes an operation of injecting charge into the fourth memory cell transistor when writing data.

10. A control method of a semiconductor storage device,
the semiconductor storage device comprising:
a multi-layered body including a plurality of gate electrode layers and a plurality of insulating layers, the plurality of gate electrode layers and the plurality of insulating layers being alternately stacked one by one in a first direction; and
a columnar body extending in the first direction within the multi-layered body, the columnar body including a memory film and a channel layer, wherein
the plurality of gate electrode layers include a first gate electrode layer, a second gate electrode layer, a third gate electrode layer, a fourth gate electrode layer, the second gate electrode layer being on a first side in the first direction with respect to the first gate electrode layer, the second gate electrode layer being adjacent to the first gate electrode layer among the plurality of gate electrode layers, the third gate electrode layer being on a second side opposite to the first side in the first direction with respect to
the first gate electrode layer, the fourth gate electrode layer being between the first gate electrode layer and the third gate electrode layer, the fourth gate electrode layer being adjacent to the third gate electrode layer among the plurality of gate electrode layers, the plurality of insulating layers include a first insulating layer, a second insulating layer, a third insulating layer, a fourth insulating layer, the first insulating layer being adjacent to the first gate electrode layer from the second side, the second insulating layer being between the first gate electrode layer and the second gate electrode layer, the third insulating layer being between the third gate electrode layer and the fourth gate electrode layer, the fourth insulating layer being adjacent to the fourth gate electrode layer from the first side,
when a direction orthogonal to the first direction is defined as a second direction, when viewed in a cross section in the first direction and the second direction,
a first boundary is between the first gate electrode layer and the first insulating layer,
the first boundary extends in the second direction,
a second boundary is between the first gate electrode layer and the second insulating layer,
the second boundary extends in the second direction,
a third boundary is between the second gate electrode layer and the second insulating layer,
the third boundary extends in the second direction,
a fourth boundary is between the third gate electrode layer and the third insulating layer,
the fourth boundary extends in the second direction,
a fifth boundary is between the fourth gate electrode layer and the third insulating layer,
the fifth boundary extends in the second direction,
a sixth boundary is between the fourth gate electrode layer and the fourth insulating layer,
the sixth boundary extends in the second direction,
the first gate electrode layer has a first edge adjacent to the columnar body at the first boundary,
the first gate electrode layer has a second edge adjacent to the columnar body from a side opposite to the first edge at the first boundary,
a distance between the first edge and the second edge is defined as a first distance,
the first gate electrode layer has a third edge adjacent to the columnar body at the second boundary,
the first gate electrode layer has a fourth edge adjacent to the columnar body from a side opposite to the third edge at the second boundary,
a distance between the third edge and the fourth edge is defined as a second distance,
the second gate electrode layer has a fifth edge adjacent to the columnar body at the third boundary,
the second gate electrode layer has a sixth edge adjacent to the columnar body from a side opposite to the fifth edge at the third boundary,
a distance between the fifth edge and the sixth edge is defined as a third distance,
the second distance is larger than the first distance and larger than the third distance,
the third gate electrode layer has a seventh edge adjacent to the columnar body at the fourth boundary,
the third gate electrode layer has has an eighth edge adjacent to the columnar body from a side opposite to the seventh edge at the fourth boundary,
a distance between the seventh edge and the eighth edge is defined as a fourth distance,
the fourth gate electrode layer has a ninth edge adjacent to the columnar body at the fifth boundary,
the fourth gate electrode layer has a tenth edge adjacent to the columnar body from a side opposite to the ninth edge at the fifth boundary,
a distance between the ninth edge and the tenth edge is defined as a fifth distance,
the fourth gate electrode layer has an eleventh edge adjacent to the columnar body at the sixth boundary,
the fourth gate electrode layer has a twelfth edge adjacent to the columnar body from a side opposite to the eleventh edge at the sixth boundary,
a distance between the eleventh edge and the twelfth edge is defined as a sixth distance,
the fifth distance is larger than the fourth distance and larger than the sixth distance.
the semiconductor storage device comprising:
a first memory cell transistor at a portion in which the first gate electrode layer and the columnar body intersect;
a second memory cell transistor at a portion in which the second gate electrode layer and the columnar body intersect;
a third memory cell transistor at a portion in which the third gate electrode layer and the columnar body intersect; and
a fourth memory cell transistor at a portion in which the fourth gate electrode layer and the columnar body intersect,
the control method, when writing data, comprising:
performing a second write operation of injecting charge into the second memory cell transistor after a first write operation of injecting charge into the first memory cell transistor; and
performing a fourth write operation of injecting charge into the fourth memory cell transistor after a third write operation of injecting charge into the third memory cell transistor.

11. A manufacturing method of a semiconductor storage device comprising:
forming a multi-layered body by repeatedly stacking a first layer, a second layer, and a third layer in a first direction in order of the first layer, the second layer, and the third layer, the second layer being more easily removed by a first etchant than the first layer, the third layer having insulating properties;
forming a hole extending in the first direction within the multi-layered body;
forming a step between the second layer and the third layer by supplying the first etchant to the inside of the hole to perform etching and remove a part of the second layer;
forming a columnar body including a memory film and a channel layer inside the hole; and
removing the first layer and the second layer by etching to form a gate electrode layer in a space in which the first layer and the second layer have been removed.
